(19) United States
(12) Patent Application Publication
(10) Pub. No.: US 2023/0341272 A1
(43) Pub. Date: Oct. 26, 2023

(54) SEMICONDUCTOR DEVICE AND CAPACITIVE SENSOR DEVICE

(71) Applicant: LAPIS Technology Co., Ltd., Yokohama (JP)

(72) Inventor: Masayuki Otsuka, Yokohama (JP)

(73) Assignee: LAPIS Technology Co., Ltd., Yokohama (JP)

(21) Appl. No.: 18/304,320

(22) Filed: Apr. 20, 2023

(30) Foreign Application Priority Data
Apr. 26, 2022 (JP) 2022-072023

(51) Int. Cl. G01K 3/00; H03K 17/56; G01K 11/06

(52) U.S. Cl. CPC G01K 3/005; H03K 17/56; G01K 11/06

(57) ABSTRACT

The disclosure includes: an electrode pad connected between a capacitor that is a target of detection and a first node for externally connecting the capacitor; a reference capacitive circuit that has a reference electrostatic capacity and applies the reference electrostatic capacity to a second node; a determination circuit that includes first and second relay terminals, supplies a charging current from the first relay terminal to an electrode pad via the first node, supplies a charging current from the second relay terminal to the reference capacitive circuit via the second node, and subsequently detects electrostatic capacity of the capacitor and determines whether or not the electrostatic capacity of the capacitor has changed by comparing magnitudes of potentials at the first relay terminal and the second relay terminal; and a correction capacitive circuit that applies a designated electrostatic capacity to the first node and is capable of varying the electrostatic capacity.

### CROSS-REFERENCE TO RELATED APPLICATION

This application claims priority under 35 USC 119 from Japanese Patent Application No. 2022-072023 filed on Apr. 26, 2022, the disclosure of which is incorporated by reference herein.

### BACKGROUND

### Technical Field

The disclosure relates to a semiconductor device and a capacitive sensor device including a capacitive sensor circuit for detecting a change in electrostatic capacity of a capacitor.

### Description of Related Art

An IC tag having a function of detecting a history of change in environment temperature to which an article is exposed during transport or storage of the article and transmitting the detected information in a wireless manner has been proposed (Patent Document 1 (Japanese Patent Application Laid-Open No. 2007-333484), for example).

In the IC tag, a sensor capacitor configured of a capacitor obtained by filling a part between electrodes with a mass of wax as a dielectric element and an absorption part that absorbs the wax in a liquid form in a case where the mass of wax is liquefied is used as a sensor for detecting a change in environment temperature. In other words, once the environment temperature reaches a temperature that is as high as a melting point of the wax, the wax with which the part between the electrodes is filled is liquefied and is then absorbed by the absorption part, and the region sandwiched between the electrodes is filled with air in the sensor capacitor. At this time, since the dielectric constant of the air is smaller than the dielectric constant of the wax, the electrostatic capacity in the sensor capacitor is reduced while an impedance increases.

Thus, the IC tag is provided with a circuit that detects the impedance as electrostatic capacity of the sensor capacitor and transmits data indicating the detection result in a wireless manner.

The data transmitted from the IC tag in a wireless manner is received by a predetermined receiving device. The receiving device compares a predetermined threshold value with the received detection result, that is, the value of the impedance of the sensor capacitor and determines whether or not the wax has been melted. At this time, in a case where the wax is determined to have been melted, it is confirmed that the IC tag has been exposed to a high temperature environment exceeding the melting point of the wax until now.

Also, a capacitive sensor device including a capacitive circuit for providing a reference electrostatic capacity as a reference for comparison provided inside a semiconductor device and detecting the electrostatic capacity of the capacitor inside the semiconductor device by comparing terminal potentials when the reference electrostatic capacity of the capacitive circuit and the sensor capacitor are charged and discharged, instead of using a predetermined threshold value, has been proposed as such an IC tag (see Patent Document 2 (Japanese Patent Application Laid-Open No. 2021-71363), for example).

Incidentally, there is a concern that the capacitive sensor device described in Patent Document 2 may cause an error in the aforementioned result of detecting the electrostatic capacity of the sensor capacitor due to variations in manufacturing or the like and this may lead to degradation of detection accuracy.

Thus, the disclosure provides a semiconductor device and a capacitive sensor device capable of detecting electrostatic capacity of a capacitor with high accuracy.

### SUMMARY

According to an embodiment of the disclosure, there is provided a semiconductor device including: an electrode pad connected between a capacitor that is a target of detection and a first node for externally connecting the capacitor; a reference capacitive circuit that has a reference electrostatic capacity and applies the reference electrostatic capacity to a second node; a determination circuit that includes first and second relay terminals, supplies a charging current from the first relay terminal to the electrode pad via the first node, supplies a charging current from the second relay terminal to the reference capacitive circuit via the second node, and subsequently detects electrostatic capacity of the capacitor and determines whether or not the electrostatic capacity of the capacitor has changed by comparing magnitudes of potentials at the first relay terminal and the second relay terminal; and a correction capacitive circuit that applies a designated electrostatic capacity to the first node and is capable of varying the electrostatic capacity.

According to an embodiment of the disclosure, there is provided a capacitive sensor device including: a sensor capacitor with electrostatic capacity changing in response to a change in environment; a first node to which an electrode of the sensor capacitor is connected; a reference capacitive circuit that has a reference electrostatic capacity and applies the reference electrostatic capacity to a second node; a determination circuit that includes first and second relay terminals, supplies a charging current from the first relay terminal to the electrode of the sensor capacitor via the first node, supplies a charging current from the second relay terminal to the reference capacitive circuit via the second node, and subsequently determines whether or not the electrostatic capacity of the sensor capacitor has changed by comparing magnitudes of potentials at the first relay terminal and the second relay terminal; and a correction capacitive circuit that applies a designated electrostatic capacity to the first node and is capable of varying the electrostatic capacity.

### BRIEF DESCRIPTION OF THE DRAWINGS

FIG. 1 is a perspective view representing an appearance of a sensor tag 150 including a capacitive sensor device.

FIG. 2 is a plan view of devices formed on a surface of a substrate 110 when seen through a protective plate 120 of the sensor tag 150.

FIG. 3 is a diagram illustrating a mode in which wireless communication is performed between the sensor tag 150 and a reader writer 200.

FIG. 4 is a block diagram illustrating a configuration of a circuit formed on an IC chip 100.

FIG. 5 is a block diagram illustrating a configuration of a capacitive sensor circuit 15.

FIG. 6 is a diagram representing an operation of a switching circuit SW.

FIG. 7 is a circuit diagram illustrating a configuration of a determination circuit JC.

FIG. 8 is a circuit diagram illustrating a control circuit 41, a trimming signal selection circuit 42, and a clock signal control circuit CLKC included in a calibration circuit CAL.

FIG. 9 is a circuit diagram illustrating the trimming signal generation circuit 43 included in the calibration circuit CAL.

FIG. 10 is a circuit diagram illustrating an internal configuration of a capacitive circuit CAP10 (CAP20).

FIG. 11 is a circuit diagram illustrating an internal configuration of a capacitive circuit CAP30.

FIG. 12 is a circuit diagram illustrating an internal configuration of a correction capacitive circuit TRAM 0.

FIG. 13 is a block diagram describing a state inside a capacitive sensor circuit 15 in a case where a sensor capacitor 50 is connected to electrode pads P0 and P2.

FIG. 14 is a time chart representing a calibration operation.

FIG. 15 is a time chart representing an internal operation of the determination circuit JC.

FIG. 16 is a block diagram describing a state inside the capacitive sensor circuit 15 in a case where the sensor capacitor 50 is connected to electrode pads P3 and P2.

FIG. 17 is an equivalent circuit diagram of a circuit included between the electrode pad P2 and an input terminal CIN0M2 of the switching circuit SW.

FIG. 18 is a block diagram describing a state inside the capacitive sensor circuit 15 in a test mode.

FIG. 19 is a block diagram illustrating a modification example of the capacitive sensor circuit 15.

FIG. 20 is a block diagram illustrating another configuration of the capacitive sensor circuit 15.

### DESCRIPTION OF THE EMBODIMENTS

Hereinafter, suitable embodiments of the disclosure will be described in detail. Substantially the same or equivalent parts in the description in each of the following embodiments and the accompanying drawings will be denoted with the same reference signs.

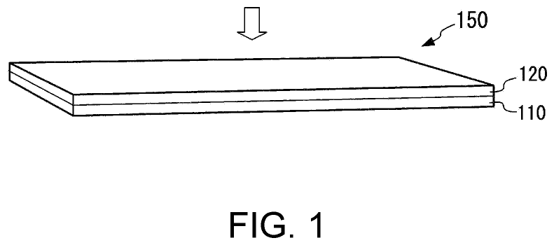

FIG. 1 is a perspective view representing an appearance of a sensor tag 150 including a capacitive sensor device according to the disclosure. The sensor tag 150 is a radio frequency identification (RFID) IC tag of a passive type, for example, including a function of detecting whether or not the sensor tag 150 itself has been exposed to a higher environment temperature than a predetermined temperature and transmitting indication thereof in a wireless manner.

The sensor tag 150 includes a substrate 110 with one surface on which a plurality of devices described below are formed and a protective plate 120 attached to the one surface of the substrate 110 to cover the plurality of devices. The substrate 110 and the protective plate 120 are flexible substrates of polyethylene terephthalate (PET), for example.

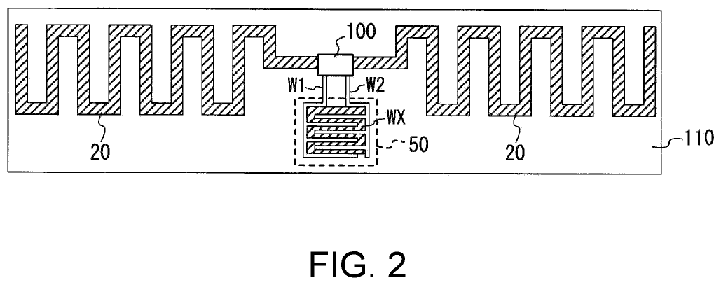

FIG. 2 is a plan view of devices formed on the surface of the substrate 110 when seen through the protective plate 120 of the sensor tag 150 in the direction of the white arrow illustrated in FIG. 1.

As illustrated in FIG. 2, devices such as an integrated circuit (IC) chip 100, an antenna 20, and a sensor capacitor 50 are formed on the one surface of the substrate 110.

The antenna 20 is made of a conductive wiring material, for example, and is connected to an electrode pad of the IC chip 100 serving as a semiconductor device.

The sensor capacitor 50 has a structure having its own electrostatic capacity irreversibly changed due to the ambient temperature and functions as a temperature sensor that detects a change in environment temperature on the basis of a change in electrostatic capacity.

For example, the sensor capacitor 50 includes comb-shaped electrodes W1 and W2 disposed along one surface on the one surface of the substrate 110 and a wax WX with which each part between comb teeth of the electrodes W1 and W2 is filled as illustrated in FIG. 2. Also, the electrodes W1 and W2 are electrodes with comb-shaped planar patterns disposed to face each other with the mutual comb teeth alternately aligned. The wax WX plays a role as a dielectric element of the capacitor. The wax WX is maintained in a solid state in a case where the environment temperature is equal to or less than a predetermined melting point and is liquefied once the environment temperature becomes higher than the melting point. Accordingly, once the sensor capacitor 50 is exposed to an environment temperature that is higher than the melting point, the wax WX serving as the dielectric element is liquefied and flows out from the part between the electrodes W1 and W2, and the electrostatic capacity of the sensor capacitor 50 decreases.

In this manner, the sensor capacitor 50 serving as a temperature sensor has predetermined first electrostatic capacity in a case where the environment temperature is equal to or less than a predetermined temperature (the melting point of the wax), and it changes to a second electrostatic capacity that is lower than the first electrostatic capacity once the environment temperature becomes higher than the predetermined temperature. Since the wax WX that has flowed out does not return even if the environment temperature returns to a temperature that is equal to or less than the melting point of the wax WX thereafter, the sensor capacitor 50 is maintained in the aforementioned state with the second electrostatic capacity.

One end of each of the electrodes W1 and W2 of the sensor capacitor 50 is connected to an electrode pad (which will be described later) serving as an external terminal of the IC chip 100.

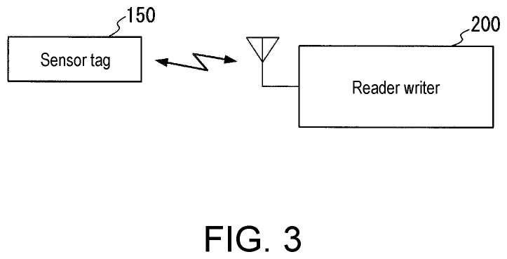

A circuit that detects the electrostatic capacity of the sensor capacitor 50 and transmits various kinds of information and an identification ID based on the electrostatic capacity to the reader writer 200 in a wireless manner as illustrated in FIG. 3 is formed in the IC chip 100 included in the sensor tag 150. Also, the various kinds of information based on the electrostatic capacity of the sensor capacitor 50 includes information indicating whether or not the IC chip 100 has been exposed to an environment temperature that is equal to or greater than the predetermined temperature, information indicating the electrostatic capacity, or the like.

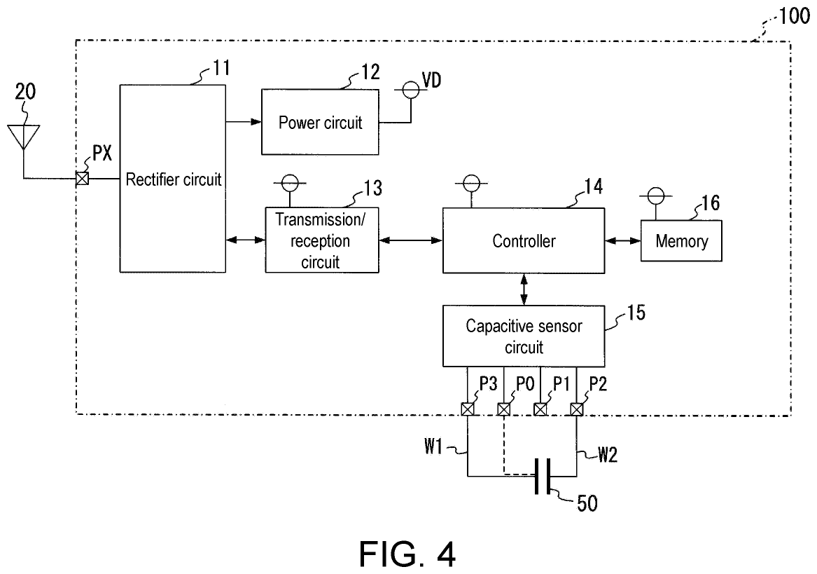

FIG. 4 is a block diagram illustrating a configuration of the circuit formed in the IC chip 100.

As illustrated in FIG. 4, a rectifier circuit 11, a power circuit 12, a transmission/reception circuit 13, a controller 14, a non-volatile memory 16 storing its own identification ID, and a capacitive sensor circuit 15 are formed in the IC chip 100.

An antenna 20 is connected to the rectifier circuit 11 via an electrode pad PX. The antenna 20 supplies a high-frequency signal representing reception information (including a command code) obtained by receiving a radio wave from the reader writer 200 and a high-frequency current for wireless power supply via the electrode pad PX and supplies them to the rectifier circuit 11.

The rectifier circuit 11 supplies a DC voltage obtained by rectifying the high-frequency current to the power circuit 12 and supplies a signal obtained by performing rectification and detection on the high-frequency signal as a reception signal to the transmission/reception circuit 13. Additionally, the rectifier circuit 11 supplies a modulation signal supplied from the transmission/reception circuit 13 to the antenna 20.

The power circuit 12 generates a power voltage VD of a constant voltage value on the basis of the DC voltage supplied from the rectifier circuit 11 and supplies the power voltage VD to the transmission/reception circuit 13, the controller 14, the memory 16, and the capacitive sensor circuit 15. Each of the transmission/reception circuit 13, the controller 14, the memory 16, and the capacitive sensor circuit 15 performs the following operation by receiving supply of such a power voltage VD. Also, the memory 16 stores the identification ID of the IC chip 100 and correction data for correcting a detection error of the electrostatic capacity of the capacitive sensor circuit 15 due to variations in manufacturing of the IC chip 100. The correction data is data indicating the electrostatic capacity corresponding to the detection error.

The transmission/reception circuit 13 acquires the command code by performing demodulation processing on the reception signal supplied from the rectifier circuit 11 and supplies the command code to the controller 14. Also, the transmission/reception circuit 13 supplies a modulation signal obtained by modulating a carrier signal that is compatible with a UHF band used for near-field wireless communication, a high-frequency (HF) band, or a low frequency (LW) band, for example, with transmission information supplied from the controller 14 to the rectifier circuit 11.

The controller 14 reads and takes the identification ID and the correction data from the memory 16 first. Then, the controller 14 supplies a capacity correction trimming signal TRM<h:0> representing the electrostatic capacity corresponding to the detection error indicated by the taken correction data with h (h is an integer that is equal to or greater than two) bits to the capacitive sensor circuit 15. Thereafter, the controller 14 supplies various control signals for detecting the electrostatic capacity of the sensor capacitor 50 to the capacitive sensor circuit 15.

The capacitive sensor circuit 15 compares the magnitudes of the electrostatic capacity of the sensor capacitor 50 and the reference electrostatic capacity in response to such various control signals. Then, the capacitive sensor circuit 15 determines whether or not the electrostatic capacity of the sensor capacitor 50 has changed from the first electrostatic capacity to the second electrostatic capacity that is lower than the first electrostatic capacity on the basis of the comparison result. The capacitive sensor circuit 15 supplies the determination result to the controller 14.

The controller 14 generates temperature change information indicating whether or not the sensor tag 150 has been exposed to the environment temperature that is higher than the predetermined temperature on the basis of the determination result and supplies information including the temperature change information and its own identification ID as the aforementioned transmission information to the transmission/reception circuit 13.

In this manner, the sensor tag 150 transmits the temperature change information indicating whether or not the sensor tag 150 itself has been exposed to the environment temperature that is higher than the predetermined temperature and the identification ID to the reader writer 200 in a wireless manner as illustrated in FIG. 3.

Hereinafter, the configuration of the capacitive sensor circuit 15 will be described in detail.

The capacitive sensor circuit 15 is connected to electrode pads P0 to P3 that are external terminals of the IC chip 100 as illustrated in FIG. 4. The electrode pads P0 to P3 are so-called bonding pads, and all of them have parasitic capacity of the same capacity value.

Here, P0 and P3 from among the electrode pads P0 to P3 are electrode pads for externally connecting the electrode W1 that is one of the aforementioned electrodes W1 and W2 of the sensor capacitor 50. Also, the electrode pad P2 is an electrode pad for externally connecting the other electrode W2 out of the electrodes W1 and W2 of the sensor capacitor 50.

Here, the electrode pad P0 is an electrode pad for connecting the electrode W1 of the sensor capacitor 50 in a case where the electrostatic capacity of the sensor capacitor 50 is relatively low. On the other hand, the electrode pad P3 is an electrode pad for connecting the electrode W1 of the sensor capacitor 50 in a case where the electrostatic capacity of the sensor capacitor 50 is relatively high.

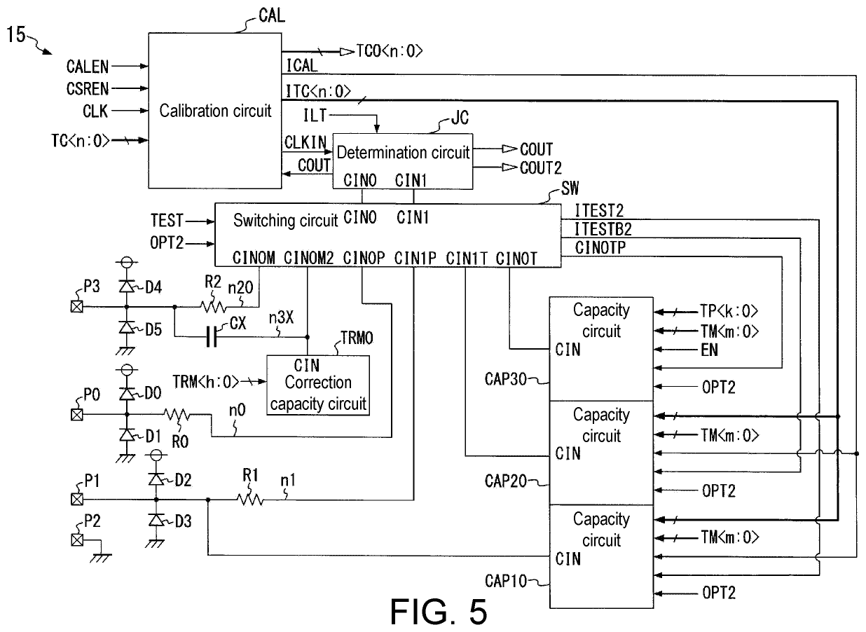

FIG. 5 is a block diagram illustrating a configuration of the capacitive sensor circuit 15.

The capacitive sensor circuit 15 includes diodes D0 to D5, resistors R0 to R2, a calibration circuit CAL, a determination circuit JC, a switching circuit SW, an additional capacitor CX, a first capacitive circuit CAP10, a second capacitive circuit CAP20, a third capacitive circuit CAP30, and a correction capacitive circuit TRM0.

An anode of the diode D0, a cathode of the diode D1, and one end of the resistor R0 are connected to the electrode pad P0. The power voltage is applied to a cathode of the diode D0, and an anode of the diode D1 is grounded. The other end of the resistor R0 is connected to an input terminal CIN0P of the switching circuit SW via a node n0.

An anode of the diode D2, a cathode of the diode D3, a capacity connection terminal CIN of the first capacitive circuit CAP10, and one end of the resistor R1 are connected to the electrode pad P1. The power voltage is applied to a cathode of the diode D2, and an anode of the diode D3 is grounded. The other end of the resistor R1 is connected to an input terminal CIN1P of the switching circuit SW via a node n1.

The electrode pad P2 is grounded.

An anode of the diode D4, a cathode of the diode D5, one end of the resistor R2, and one end of an additional capacitor CX are connected to the electrode pad P3. The power voltage is applied to a cathode of the diode D4, and an anode of the diode D5 is grounded. The other end of the resistor R2 is connected to an input terminal CIN0M of the switching circuit SW via a node n20.

The other end of the additional capacitor CX is connected to an input terminal CIN0M2 of the switching circuit SW and the capacity connection terminal CIN of the correction capacitive circuit TRM0 via a node n3X.

Also, a capacitor with any structure, such as a metal-insulator-metal (MIM) capacitor, a metal oxide metal (MOM) capacitor, or a metal oxide semiconductor (MOS) capacitor, for example, may be used as the additional capacitor CX. Additionally, diodes that have the same parasitic capacity of cathodes and the same parasitic capacity of anodes are used for all of the diodes D0 to D5. Moreover, the resistance values of the resistors R0 to R2 are the same.

The diodes D0 to D5 and the resistors R0 to R2 described above configure a protective circuit that protects the internal circuits (SW, JC, CAL, CAP10, CAP20, and CAP30) from static electricity entering them from the outside of the IC chip 100 via the electrode pads P0 to P3. Furthermore, since the parasitic capacity of each of the resistors R0 to R2 and the nodes n0, n1, and n20 plays a role as a filter, resistance against noise entering them from the outside of the IC chip 100 via the electrode pads P0, P1, and P3 is high.

The capacity connection terminal CIN of the second capacitive circuit CAP20 is connected to an input terminal CIN1T of the switching circuit SW, and the capacity connection terminal CIN of the third capacitive circuit CAP30 is connected to an input terminal CIN0T of the switching circuit SW.

The switching circuit SW receives a test mode signal TEST and a switching signal OPT2, each of which has two values (a ground potential and a power potential, for example) from the controller 14. Hereinafter, the higher potential out of the two values will be referred to as an H level, and the lower potential will be referred to as an L level. The switching circuit SW sets states of the input terminals CIN0M, CIN0M2, CIN0P. CIN1P, CIN1T, and CIN0T on the basis of such a test mode signal TEST and the switching signal OPT2. Further, the switching circuit SW generates the test signal ITEST2 of two values, an inverted test signal ITESTB2, and a signal CIN0TP on the basis of the test mode signal TEST and the switching signal OPT2.

Also, the test mode signal TEST is a signal having an H level in a case where a test for checking whether or not the capacitive sensor circuit 15 has performed a detecting operation and calibration (which will be described later) normally is carried out for the IC chip 100 alone or having an L level otherwise. Additionally, the switching signal OPT2 has an L level in a case where the sensor capacitor 50 is connected between the electrode pads P2 and P0 of the IC chip 100 or has an H level in a case where the sensor capacitor 50 is connected between the electrode pads P2 and P3.

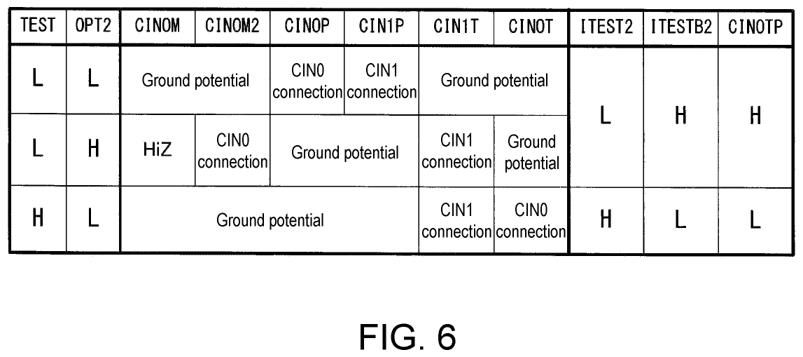

FIG. 6 is a diagram representing operations of the switching circuit SW.

In other words, the switching circuit SW sets the input terminals CIN0M, CIN0M2, CIN1T, and CIN0T in a ground potential state in a case where both the test mode signal TEST and the switching signal OPT2 are in the L level. Further, the switching circuit SW connects the input terminal CIN0P to the first relay terminal CIN0 of the switching circuit SW itself and connects the input terminal CIN1P to the second relay terminal CIN1 of the switching circuit SW itself at this time.

Also, the switching circuit SW sets the input terminal CIN0M in a high impedance state in a case where the test mode signal TEST is in the L level and the switching signal OPT2 is in the H level and sets CIN0P, CIN1P, and CIN0T in the ground potential state. Further, the switching circuit SW connects the input terminal CIN0M2 to the relay terminal CIN0 and connects the input terminal CIN1T to the relay terminal CIN1 at this time.

Also, the switching circuit SW sets the input terminals CIN0M, CIN0M2, CIN0P, and CIN1P in the ground potential state in a case where the test mode signal TEST is in the H level and the switching signal OPT2 is in the L level. Further, the switching circuit SW connects the input terminal CIN1T to the relay terminal CIN1 and connects the input terminal CIN0T to the relay terminal CIN0 at this time.

Additionally, the switching circuit SW generates a test signal ITEST2 having an L level in a case where both the test mode signal TEST and the switching signal OPT2 are in the L level, having an L level in a case where the test mode signal TEST is in the L level and the switching signal OPT2 is in the H level, and having an H level in a case where the test mode signal TEST is in the H level and the switching signal OPT2 is in the L level. The switching circuit SW supplies the test signal ITEST2 to the first capacitive circuit CAP10 and supplies an inverted test signal ITESTB2 obtained by inverting the level of the test signal ITEST2 (inverted from the L level to the H level or from the H level to the L level) to the second capacitive circuit CAP20.

Additionally, the switching circuit SW generates a signal CIN0TP having an L level in a case where the test mode signal TEST is in the H level and the switching signal OPT2 is in the L level or having an H level otherwise. The switching circuit SW supplies the signal CIN0TP to the third capacitive circuit CAP30.

The relay terminal CIN0 of the switching circuit SW is connected to the relay terminal CIN0 of the determination circuit JC, and the relay terminal CIN1 of the switching circuit SW is connected to the relay terminal CIN1 of the determination circuit JC.

The determination circuit JC charges and discharges the sensor capacitor 50 via the relay terminal CIN0, the node n0 (or n20), the resistor R0 (or R2), and the electrode pad P0 (or P3). Also, the determination circuit JC charges and discharges the capacitive circuit CAP10 via the relay terminal CIN1, the node n1, and the resistor R1. In addition, the determination circuit JC charges and discharges the capacitive circuit CAP20 via the relay terminal CIN1. Moreover, the determination circuit JC charges and discharges the capacitive circuit CAP30 via the relay terminal CIN0.

In addition, the determination circuit JC compares magnitudes of the potential of the relay terminal CIN0 generated by charging and discharging the sensor capacitor 50 and of the potential of the relay terminal CIN1 generated by charging and discharging the capacitive circuit CAP10 (or CAP20). At this time, the determination circuit JC determines whether or not the electrostatic capacity of the sensor capacitor 50 has changed from the first electrostatic capacity to the second electrostatic capacity on the basis of the result of the comparison and supplies a detection signal COUT indicating the determination result to the calibration circuit CAL and the controller 14. Further, the determination circuit JC determines whether a difference between the potential of the relay terminal CIN0 and the potential of the relay terminal CIN1 is smaller than a predetermined value, that is, whether or not both the potentials are substantially the same, and supplies a flag signal COUT2 indicating the determination result to the controller 14.

Also, the determination circuit JC executes a leakage test of itself in accordance with a leakage test signal ILT supplied from the controller 14.

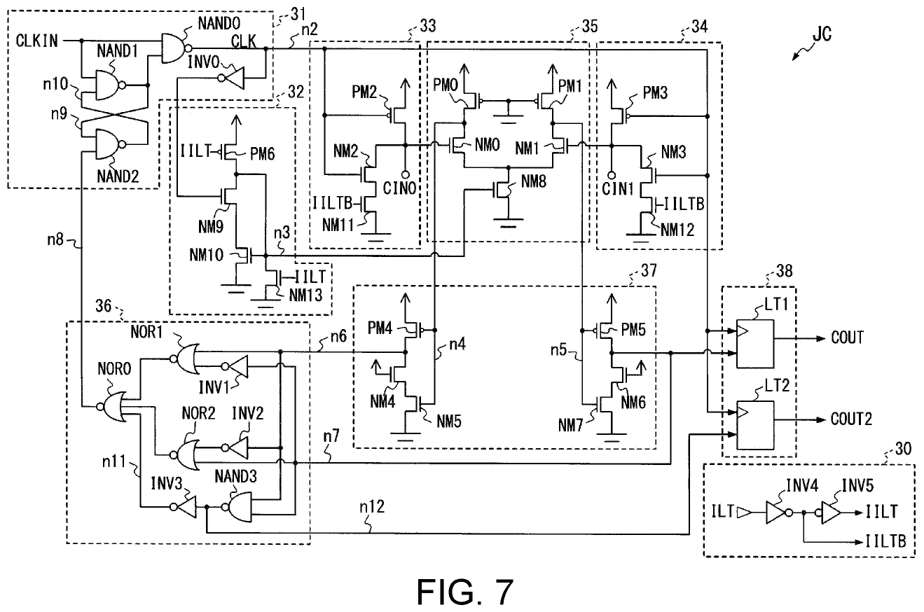

FIG. 7 is a circuit diagram illustrating a configuration of the determination circuit JC.

As illustrated in FIG. 7, the determination circuit JC includes a leakage test reception part 30, a control part 31, a bias signal generation part 32, a first current supply part 33, a second current supply part 34, a differential amplifier part 35, a timing generation circuit 36, an inverter part 37, and a data latch part 38.

The leakage test reception part 30 is configured of an inverter INV4 and an inverter INV5. An output terminal of the inverter INV4 is connected to an input terminal of the inverter INV5.

The inverter INV4 receives the leakage test signal ILT at its input terminal, supplies a signal obtained by inverting its level as an inverted signal IILTB to each of the current supply parts 33 and 34, and also supplies this to the inverter INV5. The inverter INV5 supplies a signal obtained by inverting the level of the inverted signal IILTB as a control signal IILT to the bias signal generation part 32.

The control part 31 is configured of NAND0, NAND 1, NAND2, and the inverter INV0.

NAND0, NAND1, and NAND2 are NAND gate circuits with two inputs that output negative AND. NAND0 receives a clock signal CLKIN at one of input terminals. NAND1 and NAND2 configure a flipflop circuit. NAND 1 receives the clock signal CLKIN at one of the input terminals. An output terminal of NAND1 is connected to the other input terminal of NAND0. One of input terminals of NAND2 is connected to the other input terminal of NAND0 along with the output terminal of NAND1 via the node n9. An output terminal of NAND2 is connected to the other input terminal of NAND1 via the node n10. NAND0 is maintained in an L level state when the output of NAND 1 is in the H level and outputs a signal obtained by inverting the level of the clock signal CLKIN as a clock signal CLK to the node n2 when the output of NAND1 is in the L level. The inverter INV0 has an input terminal connected to an output terminal of NAND0 via the node n2. The inverter INV0 supplies a signal obtained by inverting the level of the output signal of NAND0 input to the input terminal as an inverted clock signal to the bias signal generation part 32.

The bias signal generation part 32 includes a transistor PM6, a transistor NM9, a transistor NM10, and a transistor NM13.

The transistor PM6 is configured of a P-channel metal oxide semiconductor field effect transistor (MOSFET). A source of the transistor PM6 is connected to a power source, and a drain thereof is connected to the node n3. The transistor PM6 receives the control signal IILT at its own gate. The transistors NM9, NM10, and NM13 are configured of N channel MOSFETs that are second conductive-type transistors. The transistor NM9 receives the inverted clock signal output by the inverter INV0 at its own gate. A drain of the transistor NM9 is connected to the node n3, and a source thereof is connected to a drain of the transistor NM10. A source of the transistor NM10 is grounded, and a gate thereof is connected to the node n3. The transistor NM13 is configured of an N-channel MOSFET. A source of the transistor NM13 is grounded, and a drain thereof is connected to the node n3. The transistor NM13 receives the aforementioned supply of the control signal IILT at its own gate.

The current supply part 33 includes transistors PM2, NM2, and NM11.

The transistor PM2 is configured of a P-channel MOSFET that is a first conductor-type transistor. A power source is connected to a source of the transistor PM2, and the gate thereof is connected to the node n2. The relay terminal CIN0 is connected to a drain of the transistor PM2. The transistors NM2 and NM11 are configured of N-channel MOSFETs that are second conductive-type transistors. A gate of the transistor NM2 is connected to the node n2, and the relay terminal CIN0 is connected to a drain thereof. A drain of the transistor NM11 is connected to a source of the transistor NM2. A source of the transistor NM1 is grounded, and the transistor NM11 receives the inverted signal IILTB at its own gate.

The current supply part 34 includes transistors PM3, NM3 and NM12.

The transistor PM3 is configured of a P-channel MOSFET that is a first conductive-type transistor. A power source is connected to a source of the transistor PM3, and the node n2 is connected to a gate thereof. The relay terminal CIN1 is connected to a drain of the transistor PM3. The transistors NM3 and NM12 are configured of N-channel MOSFETs that are second conductive-type transistors. A gate of the transistor NM3 is connected to the node n2, and the relay terminal CIN1 is connected to a drain thereof. A drain of the transistor NM12 is connected to a source of the transistor NM3. A source of the transistor NM12 is grounded, and the transistor NM12 receives the inverted signal IILTB at its own gate.

The differential amplifier part 35 is a differential amplification circuit that amplifies and then outputs a potential difference between the relay terminals CIN0 and CIN1. The differential amplifier part 35 includes transistors PM0, PM1, NM1, NM1, and NMB.

The transistors PM0 and PM1 are configured of P-channel MOSFETs that are first conductive-type transistors. A source of each of the transistors PM0 and PM1 is connected to a power source, and both gates thereof are connected to each other and are also grounded in common. A drain of the transistor PM0 is connected to the node n4 and a drain of the transistor NM0. A drain of the transistor PM1 is connected to the node n5 and a drain of the transistor NM1.

The transistors NM0, NM1, and NM8 are configured of N-channel MOSFETs that are second conductive-type transistors. A gate of the transistor NM0 is connected to the drain of the transistor PM2 and a drain of the transistor NM2 and is also connected to the relay terminal CIN0. A gate of the transistor NM1 is connected to the drain of the transistor PM3 and a drain of the transistor NM3 and is also connected to the relay terminal CIN1.

A source of the transistor NM8 is grounded, and a drain thereof is connected to sources of the transistors NM0 and NM1. A gate of the transistor NM8 is connected to the node n3, is connected to a gate of the transistor NM10 via the node n3, and is connected to a drain of the transistor PM6 and a drain of the transistor NM9. The transistor NM8 has a function as a constant current source circuit. A constant current (tail current) sent by the transistor NM8 serving as the constant current source circuit is controlled by a bias signal (that is, the potential of the node n3) from the bias signal generation part 32.

The timing generation circuit 36 includes NOR0, NOR1, NOR2, NAND3, an inverter INV1, an inverter INV2, and an inverter INV3.

The inverter INV1 has an input terminal connected to the node n7. The inverter INV1 supplies an inverted signal obtained by inverting the level of the signal of the node n7 to NOR1. The inverter INV2 has an input terminal connected to the node n6. The inverter INV2 supplies an inverted signal obtained by inverting the level of the signal of the node n6 to NOR2.

NOR1 and NOR2 are NOR gate circuits with two inputs that output negative OR. One of input terminals of NOR 1 is connected to the node n6 in common with an input terminal of the inverter INV2. The other input terminal of NOR1 is connected to an output terminal of the inverter INV1. NOR1 supplies a signal of negative OR of the signal of the node n6 and the inverted signal output from the inverter INV1 to NOR0.

One of input terminals of NOR2 is connected to the node n7 in common with an input terminal of the inverter INV1. The other input terminal of NOR2 is connected to an output terminal of the inverter INV2. NOR2 supplies a signal of negative OR of the signal of the node 7 and the inverted signal output from the inverter INV2 to NOR0.

The NAND3 is a NAND gate circuit with two inputs that outputs negative AND. One of input terminals of NAND3 is connected to the node n6. The other input terminal of NAND3 is connected to the node n7. NAND3 supplies a signal representing negative AND of the signal of the node n6 and the signal of the node n7 to the inverter INV3 and supplies the signal to the data latch part 38 via the node n12.

The inverter INV3 supplies a signal obtained by inverting the level of the signal output from NAND3 to NOR0 via the node n11.

NOR0 is a NOR gate circuit with three inputs that outputs negative OR. NOR0 supplies a signal representing a result of negative OR of the signal output from each of NOR1, NOR2, and the inverter INV3 to NAND2 of the control part 31 via the node n8.

The inverter part 37 is a circuit part that inverts an output signal from the differential amplifier part 35 and outputs the inverted signal. The inverter part 37 includes transistors PM4, PM5, NM4, NM5, NM6, and NM7.

The transistors PM4 and PM5 are configured of P-channel MOSFETs that are first conductive-type transistors, and the transistors NM4 to NM7 are configured of N-channel MOSFETS that are second conductive-type transistors.

A source of the transistor PM4 is connected to a power source, and a gate thereof is connected to the node n4. A gate of the transistor NM4 is connected to a power source, and a drain thereof is connected to the node n6 in common with the drain of the transistor PM4. The transistor NM5 is configured of an N-channel MOSFET that is a second conductive-type transistor. A source of the transistor NM5 is grounded, a drain thereof is connected to a source of the transistor NM4, and a gate thereof is connected to the node n4.

A source of the transistor PM5 is connected to a power source, and a gate thereof is connected to the node n5. A gate of the transistor NM6 is connected to a power source, and a drain thereof is connected to the node n7 in common with the drain of the transistor PM5. A source of the transistor NM7 is grounded, a drain thereof is connected to a source of the transistor NM6, and a gate thereof is connected to the node n5.

With the aforementioned configurations of the differential amplifier part 35 and the inverter part 37, a signal representing whether or not the potential of the relay terminal CIN1 is greater than the potential of the relay terminal CIN0 is output to the node n6. Also, a signal representing whether or not the potential of the relay terminal CIN0 is greater than the potential of the relay terminal CIN1 is output to the node n7.

Additionally, the transistors PM0 and PM1 described above are formed to have the same dimension (the gate length, the gate width, and the like. Similarly, the transistors PM2 and PM3, the transistors PM4 and PM5, the transistors NM0 and NM1, the transistors NM2 and NM3, the transistors NM4 and NM6, and the transistors NM5 and NM7 are formed to have the same dimensions.

The data latch part 38 is configured of a first latch circuit LT1 and a second latch circuit LT2.

A clock signal CLK is supplied to a clock terminal of each of the latch circuits LT1 and LT2 via the node n2. The node n7 is connected to a signal input terminal of the latch circuit LT1, and the node n12 is connected to a signal input terminal of the latch circuit LT2.

The latch circuit LT1 takes a signal of the node n7 when the clock signal CLK is in the L level.

Then, when the clock signal CLK transitions from the L level to the H level, the latch circuit LT1 outputs a signal obtained by inverting the signal level of the node n7 taken immediately before that as a detection signal COUT indicating whether or not the electrostatic capacity of the sensor capacitor 50 has changed from the first electrostatic capacity to the second electrostatic capacity that is lower than the first elastic capacity. Thereafter, the latch circuit LT1 output the taken signal as the detection signal COUT while maintaining the signal level until the clock signal CLK transitions from the L level to the H level again.

The latch circuit LT2 takes the signal of the node n12 when the clock signal CLK is in the L level. Then, when the clock signal CLK transitions from the L level to the H level, the latch circuit LT2 outputs a signal obtained by inverting the signal level of the node n12 taken immediately before that as a flag signal COUT2 representing whether or not the potential of the relay terminal CIN0 and the potential of the relay terminal CIN1 are substantially the same.

The calibration circuit CAL receives a calibration enable signal CALEN, a sensor enable signal CSREN, a clock signal CLK, and a first trimming signal TC<n:0> (n is an integer that is equal to or greater than two) from the controller 14.

Also, the calibration enable signal CALEN is a signal of two values for performing switching between an ordinary mode in which the determination circuit JC is caused to execute an ordinary operation and a calibration mode in which the determination circuit JC is caused to execute a calibration operation. The calibration enable signal CALEN is brought into the H level in a case where it represents the calibration mode and is brought into the L level in the ordinary mode, for example. The sensor enable signal CSREN is a signal for switching the capacitive sensor circuit 15 into an active state (a state of the ordinary mode in which the ordinary operation is executed) and a non-active state (a state of a non-active mode). The sensor enable signal CSREN represents the non-active mode in the L level and represents the ordinary mode in the H level, for example. The first trimming signal TC<n:0> is a data signal of (n+1) bits for designating electrostatic capacity set by the first capacitive circuit CAP10 or the second capacitive circuit CAP20 (that is, the electrostatic capacity including parasitic capacity outside the IC chip 100 applied to the sensor capacitor 50). At this time, it is possible to cancel the parasitic capacity occurring outside the IC chip 100 by designating the electrostatic capacity of the first capacitive circuit CAP10 or the second capacitive circuit CAP20 with the first trimming signal TC<n:0>.

Furthermore, the calibration circuit CAL receives the detection signal COUT output from the determination circuit JC.

The calibration circuit CAL generates a control signal ICAL, a second trimming signal TCO<n:0>, a trimming signal ITC<n:0>, and a clock signal CLKIN in accordance with CALEN, CSREN, CLK, TC<n:0>, and COUT.

Hereinafter, operations of such a calibration circuit CAL will be described in detail.

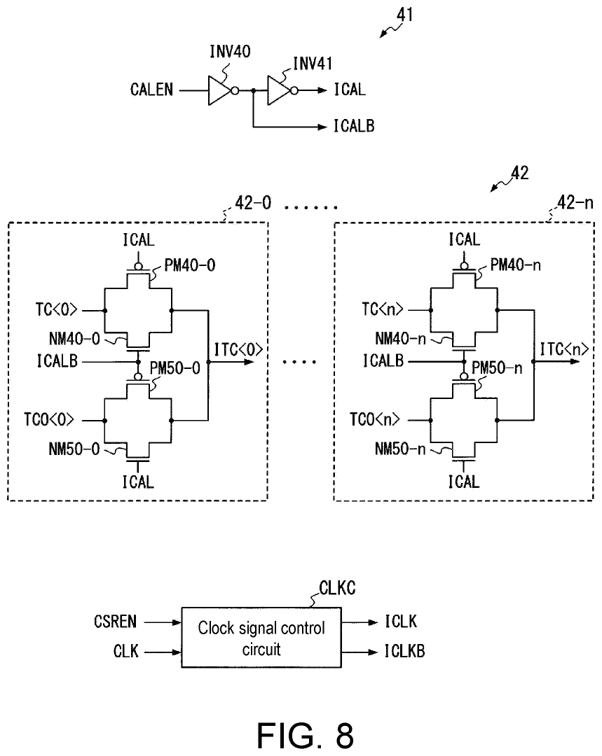

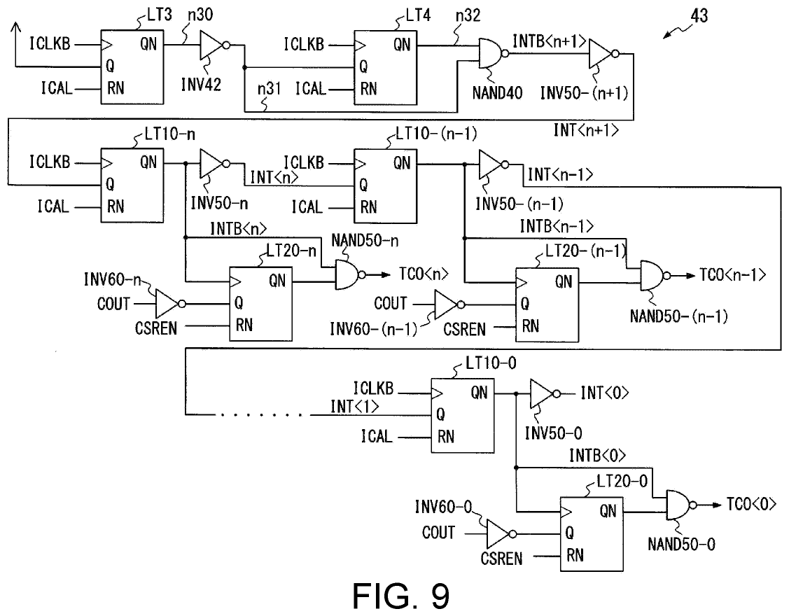

FIGS. 8 and 9 are circuit diagrams illustrating a configuration of the calibration circuit CAL.

The calibration circuit CAL includes a control circuit 41, a trimming signal selection circuit 42, and a clock signal control circuit CLKC illustrated in FIG. 8, and a trimming signal generation circuit 43 illustrated in FIG. 9.

The control circuit 41 is configured of an inverter INV40 and an inverter INV41.

An output terminal of the inverter INV40 is connected to an input terminal of the inverter INV41. The calibration enable signal CALEN is supplied to an input terminal of the inverter INV40. The inverter INV40 outputs a signal obtained by inverting the signal level of the calibration enable signal CALEN with two values as an inverted control signal ICALB. The inverter INV41 outputs a signal obtained by inverting the signal level of the inverted control signal ICALB as a control signal ICAL.

The control circuit 41 supplies the control signal ICAL and the inverted control signal ICALB to the first capacitive circuit CAP10 and the second capacitive circuit CAP20 as illustrated in FIG. 5 along with the trimming signal selection circuit 42 and the trimming signal generation circuit 43.

The trimming signal selection circuit 42 is configured of n+1 signal selection parts 42-0 to 42-n.

The signal selection parts 42-0 to 42-n receive first selection signals TC<0> to TC<n> and second selection signals TC0<0> to TC0<n>.

Additionally, the first selection signals TC<0> to TC<n> are signals serving as digits of the first trimming signal TC<n:0> sent from the controller 14, and each of them has two values, that is, predetermined signal levels of an L level and an H level. The second selection signals TCO<0> to TCO<n> are signals serving as digits of the second trimming signal TCO<n:0>, and each of them has signal levels of two values (an L level and an H level). Also, the second selection signals TCO<0> to TCO<n> are generated (as will be described later) by the trimming signal generation circuit 43.

The signal selection part 42-0 includes transistors PM40-0, NM40-0, PM50-0, and NM50-0. The control signal ICAL output from the control circuit 41 is supplied to a gate of the transistor PM40-0. A source of the transistor PM40-0 and a drain of the transistor NM40-0 are connected to each other and receive supply of the first selection signal TC<0>. A drain of the transistor PM40-0 and a source of the transistor NM40-0 are connected to each other.

A gate of the transistor NM40-0 and a gate of the transistor PM50-0 are connected to each other and receive supply of the inverted control signal ICALB. A source of the transistor PM50-0 and a drain of the transistor NM50-0 are connected to each other and receive supply of the second selection signal TCO<0>. The control signal ICAL output from the control circuit 41 is supplied to the gate of the transistor NM50-0. A drain of the transistor PM50-0 and a source of the transistor NM50-0 are connected to each other.

The connection part between the drain of the transistor PM40-0 and the source of the transistor 40-0 and the connection part between the drain of the transistor PM50-0 and the source of the transistor NM50-0 are connected to each other, and the signal selection part 42-0 outputs a selection signal ITC<0> from the connection terminal thereof.

The signal selection parts 42-1 to 42-n also have similar configurations. For example, the signal selection part 42-n includes transistors PM40-n, NM40-n, PM50-n, and NM50-n. The control signal ICAL output from the control circuit 41 is supplied to a gate of the transistor PM40-n. A source of the transistor PM40-n and a drain of the transistor NM40-n are connected to each other and receive supply of a first selection signal TC<n>. A drain of the transistor PM40-n and a source of the transistor NM40-n are connected to each other.

A gate of the transistor NM40-0 and a gate of the transistor PM50-n are connected to each other and receive supply of the inverted control signal ICALB. A source of the transistor PM50-n and a drain of the transistor NM50-n are connected to each other and receive supply of a second selection signal TCO<n>. The control signal ICAL output from the control circuit 41 is supplied to a gate of the transistor NM50-n. A drain of the transistor PM50-n and a source of the transistor NM50-n are connected to each other.

The connection part between the drain of the transistor PM40-n and the source of the transistor NM40-n and the connection part between the drain of the transistor PM50-n and the source of the transistor NM50-n are connected to each other, and the signal selection part 42-n outputs a selection signal ITC<n> from the connection terminal thereof.

With the aforementioned configuration, the control circuit 41 and the trimming signal selection circuit 42 select one of the first trimming signal TC<n:0> and the second trimming signal TCO<n:0> on the basis of the calibration enable signal CALEN.

In other words, the control circuit 41 and the trimming signal selection circuit 42 selects the first trimming signal TC<n:0> in a case where the calibration enable signal CALEN is in the L level. On the other hand, the control circuit 41 and the trimming signal selection circuit 42 select the second trimming signal TCO<n:0> in a case where the calibration enable signal CALEN is in the H level.

Then, the control circuit 41 and the trimming signal selection circuit 42 supplies the selected one of TC0<n:0> and TC<n:0> as the trimming signal ITC<n:0> to the first capacitive circuit CAP10 and the second capacitive circuit CAP20 as illustrated in FIG. 5.

The clock signal control circuit CLKC receives the clock signal CLK and the sensor enable signal CSREN, each of which has two values (the H level and the L level) and sent from the controller 14.

The clock signal control circuit CLKC generates the output clock signal ICLK with two values and the inverted clock signal ICLKB obtained by inverting the signal level of the output clock signal ICLK in accordance with the clock signal CLK and the sensor enable signal CSREN. In other words, the clock signal control circuit CLKC generates the output clock signal ICLK fixed to the L level when the signal level of the sensor enable signal CSREN is the L level. On the other hand, the clock signal control circuit CLKC generates the output clock signal ICLK with the same phase as that of the clock signal CLK when the signal level of the sensor enable signal CSREN is the H level.

The clock signal control circuit CLKC supplies the generated output clock signal ICLK as a clock signal CLKIN to the determination circuit JC and supplies the inverted clock signal ICLKB to the trimming signal generation circuit 43.

As illustrated in FIG. 9, the trimming signal generation circuit 43 includes latch circuits LT3, LT4, LT10-0 to 10-n, and LT 20-0 to 20-n. Also, the trimming signal generation circuit 43 includes an inverter INV42, inverters INV50-0 to 50-(n+1), and inverters INV60-0 to 60-n. Further, the trimming signal generation circuit 43 includes NAND40 and NAND50-0 to 50-n.

A signal input terminal Q of the latch circuit LT3 is connected to a power source. The inverted clock signal ICLKB is supplied to a clock terminal of the latch circuit LT3. The control signal ICAL is supplied to an input terminal RN of the latch circuit LT3. An output terminal QN of the latch circuit LT3 is connected to an input terminal of the inverter INV42 via the node n30. An output terminal of the inverter INV42 is connected to a signal input terminal Q of the latch circuit LT4 via the node n31.

The inverted clock signal ICLKB is supplied to a clock terminal of the latch circuit LT4. The control signal ICAL is supplied to an input terminal RN of the latch circuit LT4. An output terminal QN of the latch circuit LT4 is connected to one of input terminals of NAND40 via the node n32.

The other input terminal of NAND40 is connected to an output terminal of the inverter INV42. An output terminal of NAND40 is connected to an input terminal of the inverter INV50-(n+1). NAND40 supplies the output signal INTB<n+1> to the input terminal of the inverter INV50-(n+1). The inverter INV50-(n+1) supplies an output signal INT<n+1> obtained by inverting the output signal INTB<n+1> from NAND40 to the latch circuit LT10-n.

The inverted clock signal ICLKB is supplied to a clock terminal of the latch circuit LT10-n. The control signal ICAL is supplied to an input terminal RN of the latch circuit LT10-n. A signal input terminal Q of the latch circuit LT10-n is connected to an output terminal of the inverter INV50-(n+1). The latch circuit LT10-n outputs an output signal INTB<n> from an output terminal QN. The output terminal QN of the latch circuit LT10-n is connected to an input terminal of the inverter INV50-n and is connected to a clock terminal of the latch circuit LT20-n and one of input terminals of NAND50-n.

The inverter INV50-n outputs an output signal INT<n> obtained by inverting the output signal INTB<n> from the output terminal QN of the latch circuit LT10-n. An output terminal of the inverter INV50-n is connected to a signal input terminal of the latch circuit LT10-(n−1).

The inverted clock signal ICLKB is supplied to a clock terminal of the latch circuit LT10-(n−1). The control signal ICAL is supplied to an input terminal RN of the latch circuit LT10-(n−1). A signal input terminal Q of the latch circuit LT10-(n−1) is connected to an output terminal of the inverter INV50-n. The latch circuit LT10-n outputs an output signal INTB<n−1> from the output terminal QN. The output terminal QN of the latch circuit LT10-n is connected to an input terminal of the inverter INV50-(n−1) and is connected to a clock terminal of the latch circuit LT20-(n−1) and one of input terminals of NAND50-(n−1).

The inverter INV50-(n−1) outputs an output signal INT<n−1> obtained by inverting the output signal INTB<n−1> from the output terminal QN of the latch circuit LT10-(n−1).

The same applies to the following description, and the inverted clock signal ICLKB is supplied to the clock terminal to the latch circuit LT10-k (k=(n−2) to 1). The control signal ICAL is supplied to the input terminal RN of the latch circuit LT10-k. The signal input terminal Q of the latch circuit LT10-k is connected to the output terminal of the inverter INV50-(k+1). The output terminal QN of the latch circuit LT10-k is connected to the input terminal of the inverter INV50-k and is connected to the clock terminal of the latch circuit LT20-k and one of the input terminals of NAND50-k.

The inverted clock signal ICLKB is supplied to a clock terminal of the latch circuit LT10-0. The control signal ICAL is supplied to an input terminal RN of the latch circuit LT10-0. The output signal INT<1> of the inverter 50-n is supplied to a signal input terminal Q of the latch circuit LT10-0. The latch circuit LT10-0 outputs an output signal INTB<0> from an output terminal QN. The output terminal QN of the latch circuit LT10-0 is connected to an input terminal of the inverter INV50-0 and is connected to a clock terminal of the latch circuit LT20-0 and one of input terminals of NAND50-0.

The detection signal COUT output from the determination circuit JC is supplied to an input terminal of each of inverters INV60-0 to 60-n. The inverters INV60-0 to 60-n output a signal obtained by inverting the level of the detection signal COUT from their output terminals and supply it to the signal input terminal Q of each of the latch circuits L20-0 to 20-n.

An output signal of the output terminal QN of the latch circuit LT10-n is supplied to the clock terminal of the latch circuit LT20-n. An input terminal RN of the latch circuit LT20-n is connected to an enable terminal EN2 of the calibration circuit CAL, and the sensor enable signal CSREN is supplied to the input terminal RN. A signal input terminal Q of the latch circuit LT20-n is connected to an output terminal of the inverter INV60-n. An output terminal QN of the latch circuit LT20-n is connected to the other input terminal of NAND50-n.

An output signal from an output terminal QN of the latch circuit LT10-(n−1) is supplied to a clock terminal of the latch circuit LT20-(n−1). The sensor enable signal CSREN is supplied to an input terminal RN of the latch circuit LT20-(n−1). A signal input terminal Q of the latch circuit LT20(n−1) is connected to an output terminal of the inverter INV60-(n−1). An output terminal QN of the latch circuit LT20-(n−1) is connected to the other input terminal of NAND50-(n−1).

The same applies to the following description, and the output signal from the output terminal QN of the latch circuit LT10-k is supplied to the clock terminal of the latch circuit LT20-k (k is an integer from (n−2) to zero). The sensor enable signal CSREN is supplied to the input terminal RN of the latch circuit LT20-k. The signal input terminal Q of the latch circuit 20-k is connected to the output terminal of the inverter INV60-k. The output terminal QN of the latch circuit LT20-k is connected to the other input terminal of NAND50-k.

In the latch circuits LT3, LT4, LT10-0 to 10-n, and LT20-0 to 20-n, the output signals from the output terminals QN are fixed to the H level when the signal level of the signals input to the input terminals RN is the L level. On the other hand, signals obtained by inverting the signals input to the signal input terminals Q at rising of the clock terminals are output from the output terminals QN when the signal level of the signals input to the input terminals RN is the H level.

NAND50-0 to 50-n generate a signal of negative AND of the output signals from the latch circuits LT10-0 to 10-n and the output signals from the latch circuits LT20-0 to 20-n as second selection signals TCO<0> to TCO<n>. In this manner, the aforementioned second trimming signal TCO<n:0> is generated by the calibration circuit CAL and is supplied to the trimming signal selection circuit 42 and the controller 14.

Additionally, the second trimming signal TCO<n:0> is temporarily stored in the memory 16 by the controller 14. Thereafter, the controller 14 reads the second trimming signal TCO<n:0> from the memory 16 and supplies this as the first trimming signal TC<n:0> to the calibration circuit CAL every time the power is turned on.

Next, configurations of the capacitive circuits CAP10, CAP20, and CAP30 illustrated in FIG. 5 will be described.

Each of the capacitive circuits CAP10, CAP20, and CAP30 includes a plurality of capacitors and functions as a single variable capacitor having variable electrostatic capacity by selecting a capacitor to be used from the group of capacitors. In other words, each of the capacitive circuits CAP10, CAP20, and CAP30 is a variable capacitor in which one of a pair of electrodes is a capacity connection terminal CIN and the other electrode is grounded.

At this time, the electrostatic capacity of each of the capacitive circuits CAP10 and CAP20 themselves is set on the basis of the selection signal ITC<n:0> and the control signal ICAL supplied from the calibration circuit CAL and the margin trimming signal TM<m:0> of m (m is an integer that is equal to or greater than two) bits and the switching signal OPT2 supplied from the controller 14.

The electrostatic capacity of the capacitive circuit CAP30 itself is set on the basis of the margin trimming signal TM<m:0> supplied from the controller 14, a capacitance value selection signal TP<k:0> of k (k is an integer that is equal to or greater than two) bits, and the enable signal EN. Here, the capacitance value selection signal TP<k:0> is a data signal of (k+1) bits for allowing the electrostatic capacity of the capacitive circuit CAP30 to be selected on the assumption of the parasitic capacity outside the IC chip 100 applied to the sensor capacitor 50 in the test mode.

Also, the margin trimming signal TM<m:0> is activated when the enable signal EN is in the H level while the margin trimming signal TM<m:0> is inactivated when the enable signal EN is in the L level in the capacitive circuit CAP30.

Incidentally, the capacitive circuits CAP10, CAP20, and CAP30 are set to the test mode in accordance with test signals (ITEST2, ITESTB2, CIN0TP) supplied from the switching circuit SW. In other words, the capacitive circuit CAP10 is set to the non-test mode in a case where it receives the test signal ITEST2 in the L level and is set to the test mode in a case where it receives the test signal ITEST2 in the H level. The capacitive circuit CAP20 is set to the non-test mode in a case where it receives the inverted test signal ITESTB2 in the L level and is set to the test mode in a case where it receives the inverted test signal ITESTB2 in the H level. The capacitive circuit CAP30 is set to the non-test mode in a case where it receives the signal CIN0TP in the L level and is set to the test mode in a case where it receives the signal CIN0TP in the H level.

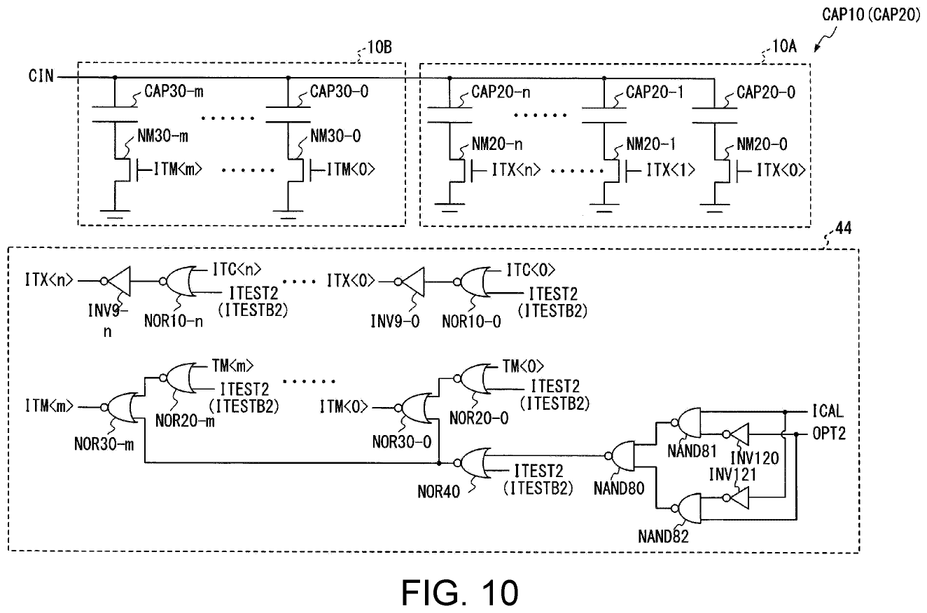

FIG. 10 is a circuit diagram illustrating configurations of the aforementioned capacitive circuits CAP10 and CAP20.

Also, in regard to the configurations of the capacitive circuits CAP10 and CAP20, circuit configurations other than that CAP10 receives the test signal ITEST2 while CAP20 receives the inverted test signal ITESTB2 are the same.

Thus, the circuit configuration of the capacitive circuit CAP10 as a representative will be described.

As illustrated in FIG. 10, the capacitive circuit CAP10 (CAP20) includes a first circuit part 10A, a second circuit part 10B, and a signal generation circuit 44.

The first circuit part 10A includes capacitors CAP20-0, CAP20-1, CAP20-n and transistors NM20-0, NM20-1, . . . , NM20-n that are N-channel MOSFETs. Each of the capacitors CAP20-0 to CAP20-n has one end connected to the capacity connection terminal CIN via a common line and the other end connected to the drain of each of the transistors NM20-1 to NM20-n. A source of each of the transistors NM20-0 to NM20-n is grounded, and selection signals ITX<0> to ITX<n> are supplied to the gate thereof.

The second circuit part 10B includes capacitor CAP30-0 to 30-m that are m+1 capacitors and transistors NM30-0 to 30-m that are m+1 N channel MOSFETs. One end of each of the capacitors CAP30-0 to 30-m is connected to the capacity connection terminal CIN via a common line. The other end of the capacitor CAP30-0 is connected to a drain of the transistor NM30-0. Similarly, the other end of each of the capacitors CAP30-1 to 30-m is connected to each of the drains of the transistors NM30-1 to 30-m. A source of each of the transistors NM30-0 to 30-m is grounded. The selection signals ITM<0> to ITM<m> are supplied to a gate of each of the transistors NM30-0 to 30-m.

The signal generation circuit 44 includes (n+1) inverters INV9-0 to 9-(n+1) and (n+1) NOR gate circuits NOR10-0 to 10-N.

Further, the signal generation circuit 44 includes two inverters INV120 and 121, three NAND gate circuits NAND80 to 82, (m+1) NOR gate circuits NOR20-0 to 20-m, (m+1) NOR gate circuits NOR30-0 to 30-m, and one NOR gate circuit NOR40.

An output terminal of each of NOR10-0 to 10-n is connected to an input terminal of each of INV9-0 to 9-n. The selection signals ITC<0> to ITC<n> output from the calibration circuit CAL are supplied to one of input terminals of each of NOR10-0 to 10-n. The test signal ITEST2 (ITESTB2 for CAP20) is supplied to the other input terminal of each of NOR10-0 to 10-n.

INV9-0 to 9-n supply signals obtained by inverting the level of output signals of NOR10-0 to 10-n as selection signals ITX<0> to ITX<n> to gates of the transistors NM20-0 to NM20-n.

An output terminal of each of NOR20-0 to 20-m is connected to one of input terminals of each of NOR30-0 to 30-m. One of input terminals of each of NOR20-0 to 20-m receives a margin trimming signal TM<m:0> sent from the controller 14. The aforementioned test signal ITEST2 (ITESTB2 for CAP20) is supplied to the other input terminal of each of NOR20-0 to 20-m.

All the other input terminals of NOR 30-0 to 30-m are connected to the output terminal of NOR40.

One of input terminals of NOR40 is connected to an output terminal of NAND80, and the aforementioned test signal ITEST2 (ITESTB2 for CAP20) is supplied to the other input terminal. The control signal ICAL output from the calibration circuit CAL is supplied to one of input terminals of NAND81, and an output terminal of INV120 is connected to the other input terminal. The switching signal OPT2 sent from the controller 14 is supplied to an input terminal of INV120. The aforementioned control signal ICAL is supplied to one of input terminals of NAND82, and an output terminal of INV121 is connected to the other input terminal. The aforementioned switching signal OPT2 is supplied to an input terminal of INV121.

Each of NOR30-0 to 30-m outputs the selection signals ITM<0> to ITM<m> and supplies them to a gate of each of the transistors NM30-0 to NM30-m.

With such a configuration, CAP10 (CAP20) is a variable capacitor with electrostatic capacity changed due to the selection signals ITC<0> to ITC<n> and the margin trimming signal TM<m:0> when it receives the test signal ITEST2 (ITESTB2) in the L level. In other words, CAP10 (CAP20) is a capacitor with its own electrostatic capacity set by the selection signals ITC<0> to ITC<n> and the margin trimming signal TM<m:0> at this time.

On the other hand, CAP10 (CAP20) is equivalent to the capacitors CAP30-0 to 30-m and a capacitor having electrostatic capacity obtained by adding electrostatic capacity of all of the capacitors CAP30-0 to 30-m when it receives the test signal ITEST2 (ITESTB2) in the H level.

Also, CAP10 is a capacitor that provides first reference electrostatic capacity for determining whether or not the electrostatic capacity of the sensor capacitor 50 has dropped below a predetermined value in a case where the sensor capacitor 50 is connected to the electrode pads P0 and P2. CAP20 is a capacitor that provides a second reference electrostatic capacity for determining whether or not the electrostatic capacity of the sensor capacitor 50 has dropped below the predetermined value in a case where the sensor capacitor 50 is connected to the electrode pads P3 and P2.

The capacitive circuit CAP30 is used for testing whether or not the capacitive sensor circuit 15 perform a detection operation and calibration (which will be described later) normally in a state where the sensor capacitor 50 is not externally connected, that is, with the IC chip 100 alone. In other words, the capacitive circuit CAP30 plays a role as the sensor capacitor 50 at the time of the test.

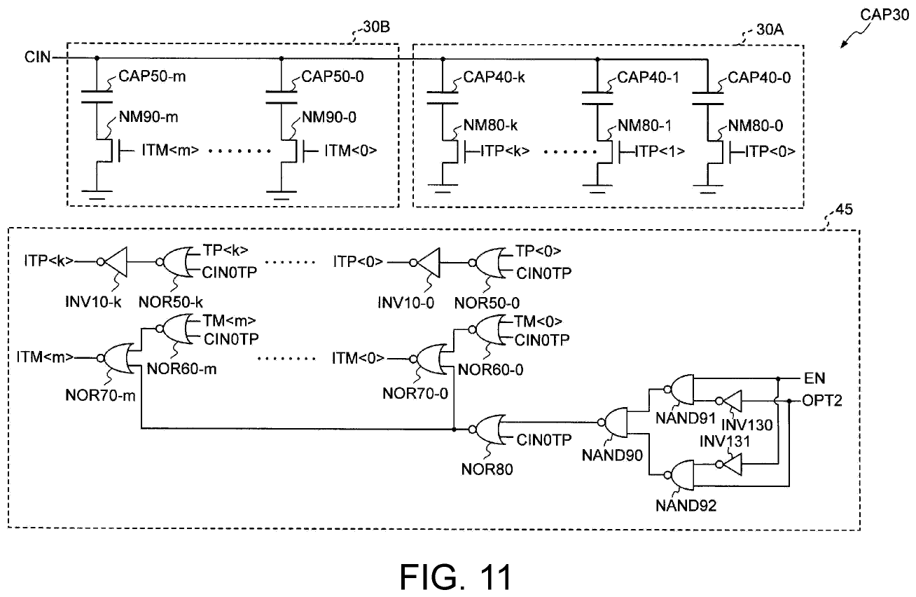

FIG. 11 is a circuit diagram illustrating a configuration of the capacitive circuit CAP30.

As illustrated in FIG. 11, the capacitive circuit CAP30 includes a first circuit part 30A, a second circuit part 30B, and a signal generation circuit 45.

The first circuit part 30A includes capacitors CAP40-0, CAP40-1, . . . , CAP40-n and transistors NM80-0, NM80-1, . . . , NM80-n that are N channel MOSFETs. Each of the capacitors CAP40-0 to CAP40-n has one end connected to the capacity connection terminal CIN via a common line and the other end connected to a drain of each of the transistors NM80-1 to NM80-n. A source of each of the transistors NM80-0 to NM80-n is grounded, and the selection signals ITP<0> to ITP<n> are supplied to a gate thereof.

The second circuit part 30B includes capacitors CAP50-0 to 50-m that are (m+1) capacitors and transistors NM90-0 to 90-m that are (m+1) N-channel MOSFETs. One end of each of the capacitors CAP50-0 to 50-m is connected to the capacity connection terminal CIN via a common line. The other end of the capacitor CAP50-0 is connected to a drain of the transistor NM90-0. Similarly, the other end of each of the capacitors CAP50-1 to 50-m is connected to a drain of each of the transistors NM90-1 to 90-m. A source of each of the transistors NM90-0 to 90-m is grounded. The selection signals ITM<0> to ITM<m> are supplied to a gate of each of the transistors NM90-0 to 90-m.

The signal generation circuit 45 includes (k+1) inverters INV10-0 to 10-k and (k+1) NOR gate circuits NOR50-0 to 50-k.

Further, the signal generation circuit 45 includes two inverters INV130 and 131, three NAND gate circuits NAND90 to 92, (m+1) NOR gate circuits NOR60-0 to 60-m, (m+1) NOR gate circuits NOR70-0 to 70-m, and one NOR gate circuit NOR80.

An output terminal of each of NOR50-0 to 50-k is connected to an input terminal of each of INV10-0 to 10-k. Each of the selection signals TP<0> to TP<k> sent from the controller 14 is supplied to one of input terminals of each of NOR 50-0 to 50-k. The signal CIN0TP output from the calibration circuit CAL is supplied to the other input terminal of each of NOR 50-0 to 50-k.

INV10-0 to 10-k supply signals obtained by inverting the level of output signals of NOR50-0 to 50-k as selection signals ITP<0> to ITP<k> to gates of the transistors NM80-0 to NM80-k.

An output terminal of each of NOR60-0 to 60-m is connected to one of input terminals of each of NOR70-0 to 70-m. One of input terminals of each of NOR60-0 to 60-m receives the margin trimming signal TM<m:0> sent from the controller 14. The aforementioned signal CIN0TP is supplied to the other input terminal of each of NOR60-0 to 60-m.

All the other input terminals of NOR70-0 to 70-m are connected to an output terminal of NOR80.

One of input terminals NOR80 is connected to an output terminal of NAND90, and the aforementioned signal CIN0TP is supplied to the other input terminal. The enable signal EN sent from the controller 14 is supplied to one of input terminals of NAND91, and an output terminal of INV130 is connected to the other input terminal. The switching signal OPT2 sent from the controller 14 is supplied to an input terminal of INV130. The aforementioned switching signal OPT2 is supplied to one of input terminals of NAND92, and an output terminal of INV131 is connected to the other input terminal. The aforementioned enable signal EN is supplied to an input terminal of INV131.

Each of NOR70-0 to 70-m outputs selection signals ITM<0> to ITM<m> and supplies them to a gate of each of the transistors NM90-0 to NM90-m.

Next, a configuration of the correction capacitive circuit TRM0 illustrated in FIG. 5 will be described.

The correction capacitive circuit TRM0 is used for increasing and correcting the amount of deviation of electrostatic capacity in a case where the result of detection of electrostatic capacity performed on the sensor capacitor 50 is confirmed to be lower than desired electrostatic capacity in a test at the time of shipping the product of the IC chip 100. The correction capacitive circuit TRM0 functions as a single variable capacitor with its own electrostatic capacity set on the basis of a capacity correction trimming signal TRM<h:0> supplied from the controller 14. The correction capacitive circuit TRM0 is a variable capacitor in which one electrode out of a pair of electrodes of the variable capacitor is grounded while the other electrode is connected to the capacity connection terminal CIN, and applies the electrostatic capacity to the node n3X via the capacity connection terminal CIN.

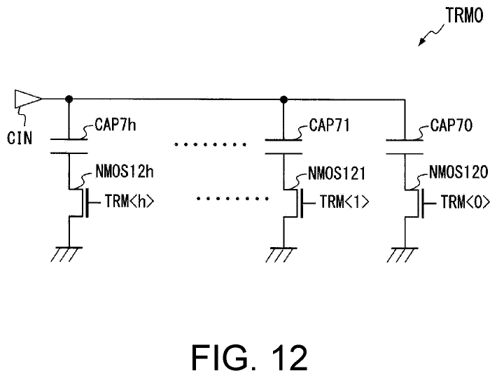

FIG. 12 is a circuit diagram illustrating a configuration of the correction capacitive circuit TRM0.

As illustrated in FIG. 12, the correction capacitive circuit TRM0 includes CAP70 to CAP7h (h is an integer that is equal to or greater than two), each of which is an independent capacitor, and a transistor NMOS120 to a transistor NMOS12h as N-channel MOSFETs. Also, the capacitors CAP70 to CAP7h may be realized by employing a metal-insulator-metal (MIM) structure or a metal-oxide-metal (MOM) structure in the semiconductor chip.

The capacity correction trimming signal TRM<0> is supplied to a gate terminal of the transistor NMOS120, and the capacity correction trimming signal TRM<1> is supplied to a gate terminal of the transistor NMOS121.

Similarly, corresponding capacity correction trimming signals TRM<2>, TRM<3>, TRM<4>, . . . , TRM<h> are supplied to gate terminals of the transistors NMOS122, NMOS123, NM0S124, . . . , NMOS12h, respectively.

Also, a source terminal of each of the transistors NMOS120 to NMOS12h is grounded as illustrated in FIG. 12. Additionally, a drain terminal of each of these transistors NMOS120, NMOS121, NMOS122, . . . , NMOS12h is connected to one electrode out of a pair of electrodes of each of the capacitors CAP70, CAP71, CAP72, . . . , CAP7h. All the other electrodes of the pairs of electrodes of the capacitors CAP70 to CAP7h are connected to the capacity connection terminal CIN.

In a case where all the capacity correction trimming signals TRM<0> to TRM<h> are in the L level, for example, all the transistors NMOS120 to NMOS12h are turned off. In this manner, all the capacitors CAP70 to CAP7h are not connected to the capacity connection terminal CIN, and the electrostatic capacity of the correction capacitive circuit TRM0 is thus set to zero. Therefore, the electrostatic capacity applied from the capacity connection terminal CIN of the correction capacitive circuit TRM0 to the node n3X in FIG. 5 becomes zero at this time.

Also, in a case where the capacity correction trimming signal TRM<0> is in the H level and all of TRM<1> to TRM<h> are in the L level, for example, only NMOS120 from among the transistors NMOS120 to NMOS12h illustrated in FIG. 12 is turned on while all the others are turned off. In this manner, only CAP70 from among the capacitors CAP70 to CAP7h is connected to the capacity connection terminal CIN, and the electrostatic capacity of the correction capacitive circuit TRM0 is thus set to the electrostatic capacity of the capacitor CAP70, and the electrostatic capacity of the capacitor CAP70 is applied to the node n3X in FIG. 5 via the capacity connection terminal CIN of the correction capacitive circuit TRM0 at this time.

Also, in a case where the capacity correction trimming signal TRM<0:1> is in the H level and all of TRM<2> to TRM<h> are in the L level, for example, only NMOS120 and NMOS121 from among the transistors NMOS120 to NMOS12h illustrated in FIG. 12 are turned on while all the others are turned off. In this manner, CAP70 and CAP71 from among the capacitors CAP70 to CAP7h are connected to the capacity connection terminal CIN, and the electrostatic capacity of the correction capacitive circuit TRM0 becomes synthetic electrostatic capacity obtained by synthesizing the electrostatic capacity of the capacitor CAP70 and the electrostatic capacity of the capacitor CAP71. At this time, the synthetic electrostatic capacity is applied to the node n3X via the capacity connection terminal CIN of the correction capacitive circuit TRM0.

Hereinafter, operations of the capacitive sensor circuit 15 will be described.

First, in a case where a sensor capacitor with relatively low electrostatic capacity is used as the sensor capacitor 50, one electrode W1 of the sensor capacitor 50 is connected to the electrode pad P0 of the IC chip 100 while the other electrode W2 of the sensor capacitor 50 is connected to the electrode pad P2 as described above. On the other hand, in a case where a sensor capacitor with relatively high electrostatic capacity is used as the sensor capacitor 50, one electrode W1 of the sensor capacitor 50 is connected to the electrode pad P3 of the IC chip 100 while the other electrode W2 of the sensor capacitor 50 is connected to the electrode pad P2.

Next, calibration of automatically calibrating the electrostatic capacity of the capacitive circuit CAP10, CAP20, or CAP30 as a variable capacitor to electrostatic capacity corresponding to the electrostatic capacity of the aforementioned sensor capacitor 50 externally connected to the IC chip 100 is performed.

Also, only CAP10 out of the capacitive circuits CAP10 and CAP20 is used in a case where the sensor capacitor 50 is connected to the electrode pads P0 and P2, and only the capacitive circuit CAP20 is used in a case where the sensor capacitor 50 is connected to the electrode pads P3 and P2, as described above. Since the calibration operation performed on each of CAP10 and CAP20 is the same at this time, a calibration operation performed on CAP10 in a case where the sensor capacitor 50 is connected to the electrode pads P0 and P2 will be described below as a representative.

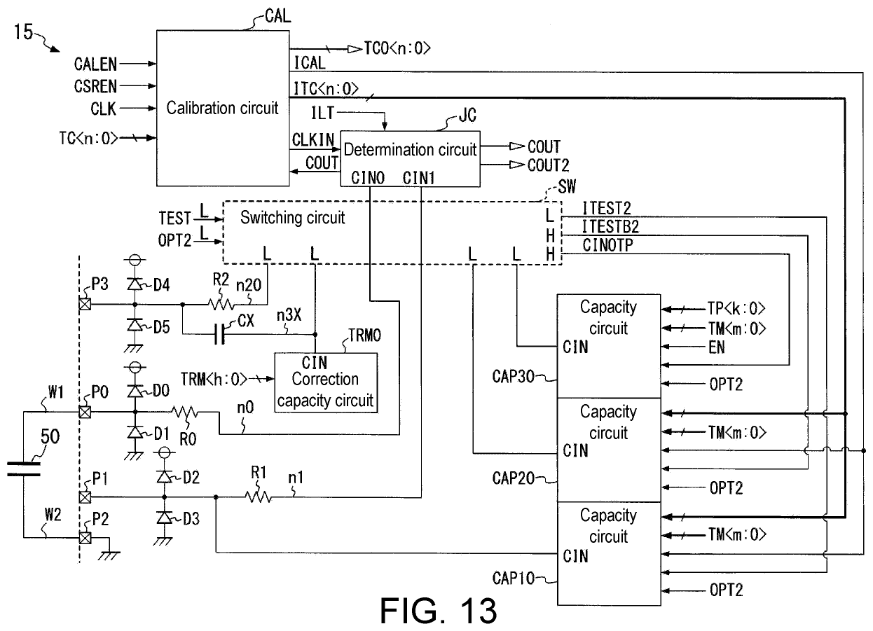

FIG. 13 is a block diagram describing a state inside the capacitive sensor circuit 15 in a case where the sensor capacitor 50 is connected to the electrode pads P0 and P2.

In other words, the controller 14 supplies the test mode signal TEST in the L level to the switching circuit SW and supplies the leakage test signal ILT in the L level to the determination circuit JC first to perform the calibration. Further, the controller 14 supplies the switching signal OPT2 in the L level for designating CAP10 out of the capacitive circuits CAP10 and CAP20 to each of the switching circuit SW, and the capacitive circuits CAP10, CAP20, and CAP30.

In this manner, the switching circuit SW connects the electrode W1 of the sensor capacitor 50 to the relay terminal CIN0 of the determination circuit JC via the node n0, the resistor R0, and the electrode pad P0 as illustrated in FIG. 13. Also, the switching circuit SW connects the capacity connection terminal CIN of the capacitive circuit CAP10 to the relay terminal CIN1 via the node n1 and the resistor R1.

Further, the switching circuit SW provides an application in the L level to the node n20, the other end of the additional capacitor CX, and the capacity connection terminal CIN of each of the capacitive circuits CAP20 an CAP30 as illustrated in FIG. 13. In this manner, both the capacity connection terminals CIN of the capacitive circuit CAP30 and the capacitive circuit CAP20 are not connected to the determination circuit JC and are thus not involved in operations of the capacitive sensor circuit 15.

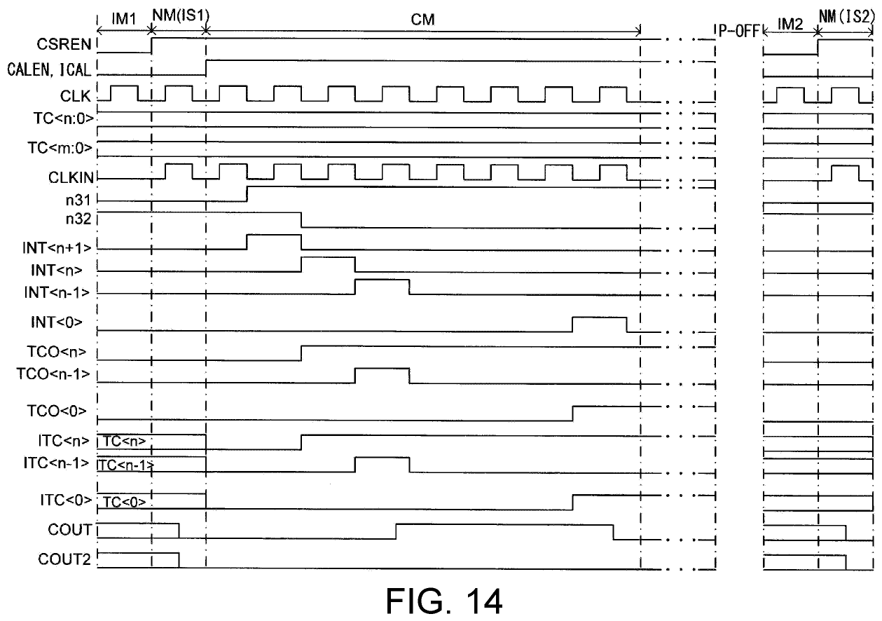

FIG. 14 is a time chart representing a calibration operation executed by the calibration circuit CAL under control of the controller 14.

### [Inactive Mode IM1]

First, the controller 14 supplies the sensor enable signal CSREN and the calibration enable signal CALEN in the L level to the calibration circuit CAL. In this manner, all the input terminals RN of the latch circuits LT20-0 to 20-n illustrated in FIG. 9 are brought into the L level. At this time, the output clock signal ICLK is brought into the L level, the inverted clock signal ICLKB is brought into the H level, the control signal ICAL is brought into the L level, and the inverted control signal ICALB is brought into the L level.

The transistors PM40-0 to 40-n of the trimming signal selection circuit 42 illustrated in FIG. 8 receive supply of the control signal ICAL in the L level at their gates and are turned on. Also, the transistors NM40-0 to 40-n receive supply of the inverted control signal ICALB in the H level at their gates and are turned on.

On the other hand, the transistors PM50-0 to 50-n receive supply of the inverted control signal ICALB in the H level at their gates and turned off. Additionally, the transistors NM50-0 to 50-n receive supply of the control signal ICAL in the L level at their gates and are turned off. In this manner, the trimming signal selection circuit 42 outputs the first selection signals TC<0> to TC<n> as selection signals ITC<0> to ITC<n>. In other words, the first trimming signal TC<n:0> is output as the trimming signal ITC<n:0>.

Also, the latch circuit LT3, the latch circuit LT4, the latch circuits LT10-0 to 10-n, and the latch circuits LT20-0 to 20-n of the trimming signal generation circuit 43 illustrated in FIG. 9 output signals in the H level from their output terminals QN. Therefore, all of INT<n+1:0> (that is, INT<n+1>, INT<n>, . . . , INT<0>) and TCO<n:0> (that is, TCO<n>, TCO<n−1>, . . . , TCO<0>) are brought into the L level.

Since the output clock signal ICLK is in the L level at this time, the clock signal CLKIN is also brought into the L level. Since the clock signal CLKIN is in the L level, the detection signal COUT and the flag signal COUT2 maintain the H levels that are data values immediately before then. FIG. 14 illustrates the period in this state as an inactive mode IM1.

[Ordinary Mode NM (Initial State IS1)]

Thereafter, the controller 14 causes the sensor enable signal CSREN to transition from the L level to the H level. In this manner, the clock signal control circuit CLKC outputs the output clock signal ICLK in the same phase as that of the clock signal CK and outputs an inverted signal of the clock signal CLK as the inverted clock signal ICLKB. Since the signal output from the output terminal QN of each of the latch circuits LT3, LT4. LT10-0 to 10-n, and LT20-0 to 20-n illustrated in FIG. 9 is still in the H level at this time, both the signals INT<n+1:0> and TCO<n:0> are maintained in the L level.

Since the output clock signal ICLK is a signal in the same phase as that of the clock signal CLK, the clock signal CLKIN is also a signal in the same phase as that of the clock signal CLK. The capacitive sensor circuit 15 is operated by rising of the clock signal CLKIN and outputs the detection signal COUT and the flag signal COUT2. If it is assumed that the dielectric element between the electrodes of the sensor capacitor 50 is in the solid form before melting and the capacity value of the capacitive circuit CAP10 is smaller than that of the sensor capacitor 50, for example, both the signal levels of the detection signal COUT and the flag signal COUT2 becomes the L level. FIG. 14 illustrates the period in this state as an ordinary mode NM (initial state IS1).

[Calibration mode CM]

Thereafter, the controller 14 causes the calibration enable signal CALEN to transition from the L level to the H level. In this manner, the control signal ICAL is brought into the H level, and the inverted control signal ICALB is brought into the L level. The transistors PM40-0 to 40-n of the trimming signal selection circuit 42 receive supply of the control signal ICAL in the H level at their gates and are turned off, and the transistors NM40-0 to 40-n receive the inverted control signal ICALB in the L level at their gates and are turned off. On the other hand, the transistors PM50-0 to 50-n receive supply of the inverted control signal ICALB in the L level at their gates and are turned on, and the transistors NM50-0 to 50-n receive the control signal ICAL in the H level at their gates and are turned on.

In this manner, the trimming signal selection circuit 42 outputs the second selection signals TCO<0> to TCO<n> as selection signals ITC<0> to ITC<n>. In other words, the second trimming signal TCO<n:0> is output as the trimming signal ITC<n:0>. Both the signals INT<n+1:0> and TCO<n:0> are in the L level, and each trimming signal ITC<n:0> is also in the L level.

Once the clock signal CLK is input to the calibration circuit CAL in this state, the potential of the node n31 of the trimming signal generation circuit 43 illustrated in FIG. 9 rises at the falling of the first clock signal CLK, and the potential of the node n32 falls at the falling of the second clock signal CLK. Therefore, the output signal INT<n+1> of the inverter INV50-(n+1) of the trimming signal generation circuit 43 is brought into the H level only between the clock of the first clock signal CLK and the second clock during the period in the calibration mode CM.

Here, the circuit configured of the latch circuits LT10-n to 10-0 in FIG. 9 and the inverters INV50-n to 50-0 is a shift resistor that outputs INT<n:0> while shifting each bit thereof. Therefore, the H pulse of the output signal INT<n+1> shifts to INT<0> in order from the output signal INT<n> after the falling of the third clock of the clock signal CLK. When the output signal INT<n> is in the H level, the output signal INTB<n> is in the L level, and the second selection signal TCO<n> is thus in the H level. At this time, all ITN<n−1:0> is in the L level.

In this manner, since the second trimming signal TCO<n:0> is output as the trimming signal ITC<n:0>, only the capacitor CAP20-n functions as the electrostatic capacity from among the capacitors CAP20-n to 20-0 of the capacitive circuit CAP10 illustrated in FIG. 10, and the other capacitors are brought into a state where they do not function. On the other hand, the control signal ICAL is also brought into the H level when the calibration enable signal CALEN is brought into the H level in the capacitors CAP30-m to 30-0. Therefore, ITM<m:0> (that is, the selection signals ITM<0> to ITM<m>) becomes the same signal as the margin trimming signal TM<m:0>, and the capacitors CAP30-m to 30-0 function as capacitors with electrostatic capacity in accordance with signal inputs of the margin trimming signal TM<m:0>.

If the clock signal CLK rises in this state, then the detection signal COUT output from the determination circuit JC is supplied to the calibration circuit CAL. Therefore, since ITNB<n> rises and ITN<n> falls at the falling of the subsequent clock signal CLK, an inverted signal obtained by inverting the detection signal COUT is stored in the latch circuit LT20-n of the trimming signal generation circuit 43 illustrated in FIG. 9. This is maintained as output data of the second section signal TCO<n> during the period in which the calibration enable signal CALEN is in the H level state.

Here, the capacitive sensor circuit 15 in the present embodiment is designed to output the detection signal COUT in the L level in the case where the dielectric element between the electrodes of the sensor capacitor 50 is in the solid state before melting and output the detection signal COUT in the H level after the melting.

In other words, the detection signal COUT is brought into the L level, and as a result, the second selection signal TCO<n> in the H level is output in a case where the determination circuit JC of the capacitive sensor circuit 15 determines that the electrostatic capacity (reference electrostatic capacity) of the capacitive circuit CAP10 is lower than the electrostatic capacity of the sensor capacitor 50. On the other hand, the detection signal COUT is brought into the H level, and as a result, the second selection signal TCO<n> in the L level is output in a case where the determination circuit JC determines that the electrostatic capacity of the capacitive circuit CAP10 is higher than the electrostatic capacity of the sensor capacitor 50.

Then, TCO<n−1> is brought into the H level, and all of INT<n−2> is maintained in the L level by the next clock. Therefore, the capacitor CAP20-n of the capacitive circuit CAP10 functions as electrostatic capacity in a case where TCO<n> is in the H level, that is, in a case where the capacitive circuit CAP10 has lower electrostatic capacity than the sensor capacitor 50. On the other hand, the capacitor CAP20-n of the capacitive circuit CAP10 is brought into a state where it does not function as a capacitor in a case where TCO<n> is in the L level, that is, the capacitive circuit CAP10 has higher electrostatic capacity than the sensor capacitor 50.

Also, only CAP 20-(n−1) from among the capacitors CAP20-(n−1) to 20-0 illustrated in FIG. 10 functions as a capacitor, and the other capacitors are brought into a state where they do not function as capacitors. If the clock signal CLK rises in this state, the detection signal COUT output from the determination circuit JC is supplied to the calibration circuit CAL. At this time, INTB<n−1> rises and INT<n−1> falls at the falling of the subsequent clock signal CLK. Therefore, an inverted signal obtained by inverting the signal level of the detection signal COUT is stored in the latch circuit LT20-(n−1) of the trimming signal generation circuit 43 illustrated in FIG. 9, and this is maintained as the second selection signal TCO<n−1> during the period in which the calibration enable signal CALEN is in the H level state.

Hereinafter, similar processing is repeated until the inverted signal obtained by inverting the signal level of the detection signal COUT is stored in the latch circuit LT20-0 and this is maintained as TCO<0> during the period in which the calibration signal CALEN is in the H level state.

In this manner, the series of operations are performed such that the capacity of the capacitive circuit CAP10 is reduced in a case where the electrostatic capacity of the sensor capacitor 50 is higher than the electrostatic capacity of the capacitive circuit CAP10 and the capacity of the capacitive circuit CAP10 is increased in a case where the electrostatic capacity of the sensor capacitor 50 is lower than the electrostatic capacity of the capacitive circuit CAP10, during the period in which the calibration enable signal CALEN is in the H level. In other words, the second trimming signal TCO<n:0> is set such that the electrostatic capacity of the capacitive circuit CAP10 becomes equal to the electrostatic capacity of the sensor capacitor 50 in the solid state. FIG. 14 illustrates the period in this state as a calibration mode CM. Also, the controller 14 supplies, to the capacitive circuit CAP10, the margin trimming signal TM<m:0> that sets, for example, a half of a difference between the electrostatic capacity of the sensor capacitor 50 before the dielectric element is melted and the electrostatic capacity of the sensor capacitor 50 after the melting as a margin during the period of the calibration mode. Then, after the calibration ends, the controller 14 stores the second trimming signal TCO<n:0> immediately after the calibration ends in the non-volatile memory 16.

[Inactive Mode IM2]

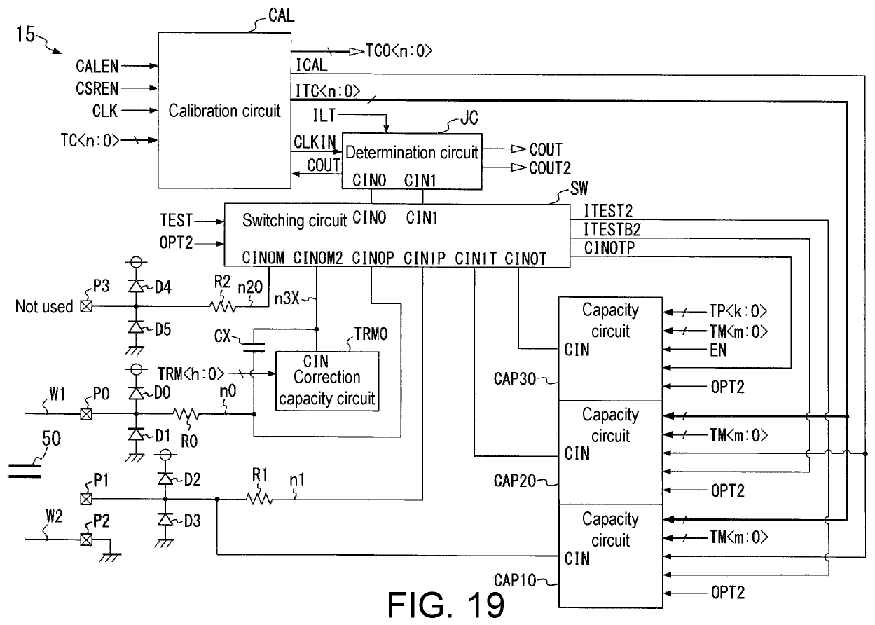

Thereafter, once the power supply is interrupted (during the period of P-OFF in FIG. 14) and the power is turned on again, then the controller 14 reads the second trimming signal TCO<n:0> from the memory 16 and supplies this as the first trimming signal TC<n:0> to the calibration circuit CAL. FIG. 19 illustrates the period in this state as an inactive mode IM2.

[Ordinary Mode NM (Initial State IS2)]

Then, the controller 14 causes the sensor enable signal CSREN to transition from the L level to the H level, supplies the calibration enable signal CALEN in the L level to the calibration circuit CAL, and causes the capacitive sensor circuit 15 to operate. Since both the calibration enable signal CALEN and the switching signal OPT2 are in the L level at this time, all of ITM<m:0> (that is, the selection signals ITM<0> to ITM<m>) of (m+1) bits of the signal generation circuit 44 illustrated in FIG. 10 is brought into the L level. In this manner, all the capacitors CAP30-0 to 30-m do not function as electrostatic capacity.

Therefore, the electrostatic capacity of the capacitive circuit CAP10, that is, the reference electrostatic capacity is set to electrostatic capacity between first electrostatic capacity of the sensor capacitor 50 before the dielectric element is melted including the parasitic capacity outside the IC chip 100 and second electrostatic capacity after the dielectric element is melted. FIG. 14 illustrates the period in this state as an ordinary mode NM (initial state IS2).

In short, the controller 14 supplies, to the second circuit part 10B, the margin trimming signal (TM) that sets the electrostatic capacity of the second circuit part 10B of the capacitive circuit CAP10 as the margin electrostatic capacity in the aforementioned series of calibration processing. The calibration circuit CAL executes calibration of supplying, to the first circuit part 10A, the trimming signal (TCO, ITC) that sets the electrostatic capacity of the first circuit part 10A of the capacitive circuit CAP10 to electrostatic capacity that changes in a stepwise manner with elapse of time.

The controller 14 causes the non-volatile memory 16 to store the trimming signal (TCO, ITC) when the determination circuit JC determines that the potential of the first relay terminal CIN0 is equal to the potential of the second relay terminal CIN1 during the execution of the calibration processing. Then, the controller 14 sets the electrostatic capacity of the first circuit part 10A of the capacitive circuit CAP10 with the trimming signal (TCO, ITC) stored in the memory 16 next time the power is turned on.

Therefore, it is possible to cancel the parasitic capacity outside the IC chip 100 and to set the electrostatic capacity of the capacitive circuit CAP10 to an intermediate level between the electrostatic capacity of the sensor capacitor 50 before the dielectric element is melted and the electrostatic capacity after the melting, through the aforementioned calibration. It is thus possible to determine whether or not the dielectric element with which the part between the electrodes of the sensor capacitor 50 is filled has been melted, with high accuracy.

Additionally, the calibration circuit CAL is used to calibrate the reference electrostatic capacity that serves as a threshold value for detecting a change in electrostatic capacity of the sensor capacitor 50 for the capacitive circuit CAP10 (or CAP20 or CAP30) in the aforementioned embodiment.

However, it is also possible to use the calibration operation of the calibration circuit CAL to detect the electrostatic capacity of the capacitor connected to the electrode pads P0 (or P3) and P2. For example, a capacitor as a target of detection for electrostatic capacity is connected to the electrode pads P0 (or P3) and P2, and the aforementioned calibration operation is then executed. If the determination circuit JC outputs the flag signal COUT2 in the H level at this time, the controller 14 takes the trimming signal ITC<n:0> output by the calibration circuit CAL at that timing. In other words, the trimming signal ITC<n:0> taken by the controller 14 at the timing when the flag signal COUT2 in the H level is output represents synthetic electrostatic capacity of the capacitors CAP20-0 to CAP20-n of the capacitive circuit CAP10, and the value is equal to the electrostatic capacity of the capacitor connected to the electrode pads P0 (or P3) and P2. Thus, the controller 14 supplies, to the transmission/reception circuit 13, information indicating the electrostatic capacity corresponding to the taken trimming signal ITC<n:0> as transmission information along with the aforementioned identification ID. In this manner, the sensor tag 150 transmits the information indicating the electrostatic capacity of the capacitor connected to the electrode pads P0 (or P3) and P2 and the identification ID to the reader writer 200 in a wireless manner as illustrated in FIG. 3. Therefore, it is possible to know the electrostatic capacity of the capacitor connected to the electrode pads P0 (or P3) and P2 of the sensor tag 150 in a wireless manner by the reader writer 200.

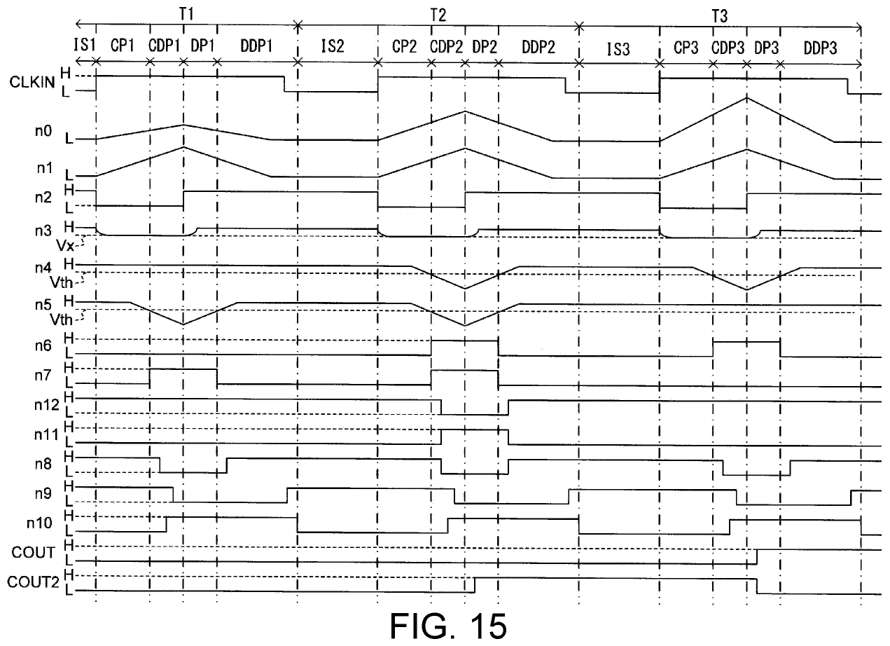

Next, internal operations of the determination circuit JC illustrated in FIG. 7 will be described with reference to the time chart illustrated in FIG. 15.

Also, FIG. 15 illustrates a period during which the dielectric element between the electrodes of the sensor capacitor 50 has not been melted as a period T1, a period during which the dielectric element has been melted to some extent and the electrostatic capacity of the sensor capacitor 50 and the electrostatic capacity of the capacitive circuit CAP10 are substantially equal to each other as a period T2, and a period after the entire dielectric element of the sensor capacitor 50 is melted as a period T3.

First, operations in the period T1 will be described.

[First Initial State IS1]

Once the clock signal CLKIN in the L level is supplied from the calibration circuit CAL to the determination circuit JC, the potential of the node n2 illustrated in FIG. 7 is brought into the H level. In this manner, the potentials of the node n0 and the node n1 are brought into the L level, and the potentials of the node n3, the node n4, and the node n5 are brought into the H level. Additionally, the potentials of the node n6 and the node n7 are brought into the L level, the potential of the node n8 is brought into the H level, the potential of the node n9 is brought into the H level, the potential of the node n10 is brought into the L level, and the potential of the node n11 is brought into the L level. FIG. 15 illustrates the period in this state as the first initial state IS1.

In the first initial state IS1, the potential of the node n2 is in the H level, and the value of the detection signal COUT output from the first latch circuit LT1 is thus a value maintained until the timing immediately before then. In other words, since the dielectric element between the electrodes of the sensor capacitor 50 is in the state before melting, the detection signal COUT in the L level is output.

Similarly, since the potential of the node n2 is in the H level, the value of the flag signal COUT2 output from the second latch circuit LT2 is also a value maintained until the timing immediately before then. In other words, since the electrostatic capacity of the sensor capacitor 50 is higher than the electrostatic capacity of the capacitive circuit CAP10, the flag signal COUT2 in the L level is output.

[First Charging Period CP1]

Thereafter, once the clock signal CLKIN transitions to the H level, the potential of the node n2 is brought into the L level. The potential of the node n2 is inverted by the inverter INV0, and an inverted signal in the H level is applied to the gate of the transistor NM9. In this manner, the bias signal generation part 32 operates, and the node n3 gets to have an intermediate potential Vx. In this manner, a bias signal in the level of the intermediate potential Vx is supplied to the gate of the transistor NM8 that is a constant current source.

Also, since the potential of the node n2 is in the L level, both the transistor NM2 and the transistor NM3 are brought into the OFF state, and both the transistors PM2 and PM3 are brought into the ON state. In this manner, the determination circuit JC sends a charging current from the relay terminals CIN0 and CIN1 to the sensor capacitor 50 and the capacitive circuit CAP10 via each of the nodes n0 and n1 to charge the sensor capacitor 50 and the capacitive circuit CAP10.

Since the dielectric element of the sensor capacitor 50 has not been melted in the period T1, the electrostatic capacity of the sensor capacitor 50 is predetermined first electrostatic capacity, which is higher than the electrostatic capacity (which will be referred to as reference electrostatic capacity) of the capacitive circuit CAP10. Therefore, the capacitive circuit CAP10 is charged earlier than the sensor capacitor 50, and the potential of the node n1 rises earlier than the node n0.

The potential of the node n1 is applied to the gate of the transistor NM1, and the potential of the node n5 drops due to an operation of the differential amplifier part 35. On the other hand, since the potential of the node n0 rises with a delay as compared with the node n1, the potential of the node n4 hardly drops due to the function of the differential amplifier part 35. FIG. 15 illustrates the period in such a state as a first charging period CP1.

[First Charging Detection Period CDP1]

Thereafter, once the potential of the node n5 drops up to a threshold level Vth of the inverter part 37, the potential of the node n7 is brought into the H level, and a signal in the H level is taken by the first latch circuit LT1. Additionally, since the potential of the node n6 is in the L level, the potential of the node n12 is maintained in the H level, and the potential of the node n11 is maintained in the L level even if the potential of the node n7 is brought into the H level. In this manner, a signal in the H level is taken by the second latch circuit LT2. FIG. 15 illustrates the period in such a state as a first charging detection period CDP1.

Also, the potentials of the nodes n8, n10, and n9 successively change with time differences in the first charging detection period CDP1. Specifically, the potential of the node n8 is brought into the L level by the potential of the node n7 being brought into the H level. The potential of the node n10 is brought into the H level in response to a change in potential of the node n8. The potential of the node n9 is brought into the L level in response to a change in potential of the node n10.

[First Discharging Period DP1]

The potential of the node n2 changes to the H level by the potential of the node n9 being brought into the L level. In this manner, a signal in the H level is supplied as a clock signal to the clock terminal of the first latch circuit LT1. At this time, since the node n7 is in the H level, the first latch circuit LT1 takes a signal in the H level and outputs a signal in the L level obtained by inverting the signal as a detection signal COUT.

Similarly, a signal in the H level is supplied as a clock signal to the clock terminal of the second latch circuit LT2. At this time, since the node n12 is in the H level, the second latch circuit L2 takes a signal in the H level and outputs a signal in the L level obtained by inverting the signal as a flag signal COUT2.

Also, an inverted signal in the L level obtained by inverting the potential of the node n2 is applied to the gate of the transistor NM9 by the potential of the node n2 being brought into the H level. In this manner, the bias signal generation part 32 is brought into the OFF state (that is, in a state where it does not operate), and the potential of the node n3 is brought into the H level. In this manner, a bias signal in the H level is supplied to the gate of the transistor NM8, and the transistor NM8 that is a constant current source is brought into the ON state. Additionally, the transistors NM2 and NM3 are brought into the ON state, the transistors PM2 and PM3 are brought into the OFF state, and the sensor capacitor 50 and the capacitive circuit CAP10 are thus discharged via the relay terminals CIN0 and CIN1. FIG. 15 illustrates the period in such a state as a first discharging period DP1.

[First Discharging Detection Period DDP1]

Thereafter, once the potential of the node n5 rises to the threshold level Vth of the inverter part 37, the potential of the node 7 is brought into the L level, and the potential of the node n8 is brought into the H level. Thereafter, once the clock signal CLKIN is brought into the L level, the potential of the node n9 is brought into the H level, and the potential of the node n10 is brought into the L level. FIG. 15 illustrates the period in such a state as a first discharging detection period DDP1.

Next, operations in a period T2 (that is, a state where the dielectric element has been melted to some extent and the electrostatic capacity of the sensor capacitor 50 and the electrostatic capacity of the capacitive circuit CAP10 have become substantially equal to each other) will be described.

[Second Initial State IS2]

Once the clock signal CLKIN in the L level is supplied to the determination circuit JC, the potential of the node n2 is brought into the H level. In this manner, the potentials of the node n0 and the node n1 are brought into the L level, and the potentials of the node n3, the node n4, and the node n5 are brought into the H level. Additionally, the potentials of the node n6 and the node n7 are brought into the L level, the potential of the node n12 is brought into the H level, the potential of the node n11 is brought into the L level, the potential of the node n8 is brought into the H level, the potential of the node n9 is brought into the H level, and the potential of the node n10 is brought into the L level. FIG. 15 illustrates the period in this state as a second initial state IS2.

Also, since the potential of the node n2 is in the H level in the second initial state IS2, the detection signal COUT output from the first latch circuit TL1 is in a state where the L level that is a previous data value is maintained. Similarly, the flag signal COUT2 output from the second latch circuit LT2 is also in a state where the L level that is a previous data value is maintained.

[Second Charging Period CP2]

Thereafter, once the clock signal CLKIN is brought into the H level, the potential of the node n2 is brought into the L level. The potential of the node n2 is inverted by the inverter INV0, and an inverted signal in the H level is applied to the gate of the transistor NM9. In this manner, the bias signal generation part 32 operates, and the node n3 gets to have the intermediate potential Vx. In this manner, a bias signal in the intermediate potential Vx level is supplied to the gate of the transistor NM8 that is a constant current source.

In addition, since the potential of the node n2 is in the L level, both the transistor NM2 and the transistor NM3 are brought into the OFF state, and both the transistors PM2 and PM3 are brought into the ON state. In this manner, the determination circuit JC sends a charging current from the relay terminals CIN0 and CIN1 to the sensor capacitor 50 and the capacitive circuit CAP10 via the nodes n0 and n1, respectively, and charges the sensor capacitor 50 and the capacitive circuit CAP10.

In the period T2, the dielectric element has been melted to some extent, and the sensor capacitor 50 and the capacitive circuit CAP10 have substantially the same electrostatic capacity (that is, the reference electrostatic capacity). Therefore, the sensor capacitor 50 and the capacitive circuit CAP10 are charged at substantially the same speed, and the potentials of the node n0 and the node n1 rise at similar rising rates (that is, a state where a difference between the rising degrees is less than a predetermined difference) with elapse of time.

The potential of the node n0 is applied to the gate of the transistor NM0, and the potential of the node n4 drops due to an operation of the differential amplifier part 35. On the other hand, the potential of the node n1 is applied to the gate of the transistor NM1, and the potential of the node n5 drops due to an operation of the differential amplifier. Since the rising rates of the potentials of the node n0 and the node n1 are substantially the same, the potentials of the node n4 and the node n5 also drop at substantially the same dropping rate (that is, a state where a difference between the dropping degrees is less than a predetermined difference). FIG. 15 illustrates the period in such a state as a second charging period CP2.

[Second Charging Detection Period CDP2]

Thereafter, once the potential of the node n4 drops to the threshold level Vth of the inverter part 37, the potential of the node n6 is brought into the H level. Similarly, once the potential of the node n5 drops to the threshold level Vth of the inverter part 37, the potential of the node n7 is brought into the H level. Since the dropping rates of the potentials of the node n4 and the node n5 are substantially the same, the potentials of the node n6 and the node n7 are brought into the H level at substantially the same time.

The potential of the node n12 is brought into the L level, and the potential of the node n11 is brought into the H level, by the potentials of the nodes n6 and n7 being brought into the H level. Additionally, the potentials of the nodes n8, n10, and n9 successively change with time differences. Specifically, the potential of the node n8 is brought into the L level by the potentials of the nodes n6 and n7 being brought into the H level and by the potential of the node n11 being brought into the H level. The potential of the node n10 is brought into the H level in response to a change in potential of the node n8. The potential of the node n9 is brought into the L level in response to a change in potential of the node n10. FIG. 15 illustrates the period in such a state as a second charging detection period CDP2.

[Second Discharging Period DP2]

Also, since the clock signal CLKIN is in the H level, and the potential of the node n9 is in the L level, the node n2 corresponding to the negative AND thereof is brought into the H level. Since the node n7 is in the H level at this time, a signal in the H level is taken by the first latch circuit LT1. Therefore, the first latch circuit LT1 outputs an inverted signal in the L level obtained by inverting the signal as the detection signal COUT. Also, since the potential of the node n12 is in the L level, a signal in the L level is taken by the second latch circuit LT2. Therefore, the second latch circuit LT2 outputs an inverted signal in the H level obtained by inverting the signal as the flag signal COUT2.

Additionally, an inverted signal in the L level obtained by inverting the potential of the node n2 is applied to the gate of the transistor NM9 by the potential of the node n2 being brought into the H level. In this manner, the bias signal generation part 32 is brought into the OFF state (that is, a state where it does not operate), and the potential of the node n3 is brought into the H level. In this manner, a bias signal in the H level is supplied to the gate of the transistor NM8, and the transistor NM8 as a constant current source is brought into the ON state. Additionally, the transistors NM2 and NM3 are brought into the ON state, the transistors PM2 and PM3 are brought into the OFF state, and the sensor capacitor 50 and the capacitive circuit CAP10 are thus discharged via the relay terminals CIN0 and CIN1. FIG. 15 illustrates the period in such a state as a second discharging period DP2.

[Second Discharging Detection Period DDP2]

Thereafter, once the potential of the node n4 rises to the threshold level Vth of the inverter part 37, the potential of the node n6 is brought into the L level. Similarly, once the potential of the node n5 rises to the threshold level Vth of the inverter part 37, the potential of the node n7 is brought into the L level. In this manner, the potential of the node n12 is brought into the H level, the potential of the node n11 is brought into the L level, and the potential of the node n8 is brought into the H level. Thereafter, once the clock signal CLKIN is brought into the L level, the potential of the node n9 is brought into the H level, and the potential of the node n10 is brought into the L level. FIG. 15 illustrates the period in such a state as a second discharging detection period DDP2.

Next, operations in a period T3 (that is, a state where the entire dielectric element has been melted) will be described.

[Third Initial State IS3]

Once the clock signal CLKIN in the L level is supplied to the determination circuit JC, the potential of the node n2 is brought into the H level. In this manner, the potentials of the node n0 and the node n1 are brought into the L level, and the potentials of the node n3, the node n4, and the node n5 are brought into the H level. Additionally, the potentials of the node n6 and the node n7 are brought into the L level, the potential of the node n12 is brought into the H level, the potential of the node n11 is brought into the L level, the potential of the node n8 is brought into the H level, the potential of the node n9 is brought into the H level, and the potential of the node n10 is brought into the L level. FIG. 15 illustrates the period in this state as a third initial state IS3.

In the third initial state IS3, the potential of the node n2 is in the H level, and the detection signal COUT output from the first latch circuit LT1 is thus in a state where the L level that is the previous data value is maintained. In addition, the flag signal COUT2 output from the second latch circuit LT2 is also in a state where the H level that is the previous data value is maintained.

[Third Charging Period CP3]

Thereafter, once the clock signal CLKIN is brought into the H level, the potential of the node n2 is brought into the L level. The potential of the node n2 is inverted by the inverter INV0, and an inverted signal in the H level is applied to the gate of the transistor NM9. In this manner, the bias signal generation part 32 operates, and the node n3 gets to have the intermediate potential Vx. In this manner, a bias signal in the intermediate potential Vx level is supplied to the gate of the transistor NM8 that is a constant current source.

Also, since the potential of the node n2 is in the L level, both the transistor NM2 and the transistor NM3 is brought into the OFF state, and both the transistors PM2 and PM3 are brought into the ON state. In this manner, the determination circuit JC sends a charging current from the relay terminals CIN0 and CIN1 to the sensor capacitor 50 and the capacitive circuit CAP10 via the nodes n0 and n1, respectively, to charge the sensor capacitor 50 and the capacitive circuit CAP10.

Since the dielectric element of the sensor capacitor 50 has been melted in the period T3, the electrostatic capacity of the sensor capacitor 50 is the second electrostatic capacity, which is lower than the reference electrostatic capacity of the capacitive circuit CAP10. Therefore, the sensor capacitor 50 is charged earlier than the capacitive circuit CAP10, and the potential of the node n0 rises earlier than that of the node n1.

The potential of the node n0 is applied to the gate of the transistor NM0, and the potential of the node n4 drops due to an operation of the differential amplifier part 35. On the other hand, the potential of the node n1 rises with a delay as compared with the node n0, and the potential of the node n5 thus hardly drops due to the function of the differential amplifier part 35. FIG. 15 illustrates the period in such a state as a third charging period CP3.

[Third Charging Detection Period CDP3]

Thereafter, once the potential of the node n4 drops to the threshold level Vth of the inverter part 37, the potential of the node n6 is brought into the H level. On the other hand, since the potential of the node n5 does not drop, the node n7 is maintained in the L level, and a signal in the L level is taken by the first latch circuit LT1. Additionally, since the potential of the node n7 is in the L level, the potential of the node n12 is maintained in the H level, and the potential of the node n11 is maintained in the L level, even if the potential of the node n6 changes to the H level. FIG. 15 illustrates the period in such a state as a third charging detection period CDP3.

In the third charging detection period CDP3, the potentials of the nodes n8, n10, and n9 successively change with time differences. Specifically, the potential of the node n8 is brought into the L level by the potential of the node n6 being brought into the H level. The potential of the node n10 is brought into the H level in response to a change in potential of the node n8. The potential of the node n9 is brought into the L level in response to a change in potential of the node n10.

[Third Discharging Period DP3]

The potential of the node n2 is brought into the H level by the potential of the node n9 being brought into the L level. In this manner, a signal in the H level is supplied as a clock signal to the clock terminal of the first latch circuit LT1. At this time, since the node n7 is in the L level, the first latch circuit LT1 takes a signal in the L level and outputs a signal in the H level obtained by inverting the level thereof as the detection signal COUT.

Also, a signal in the H level is supplied as a clock signal to the clock terminal of the second latch circuit LT2. At this time, since the node n12 is in the H level, the second latch circuit LT2 takes the signal in the H level and outputs an inverted signal in the L level obtained by inverting the signal level as the flag signal COUT2.

Additionally, an inverted signal in the L level obtained by inverting the potential of the node n2 is applied to the gate of the transistor NM9 by the potential of the node n2 being brought into the H level. In this manner, the bias signal generation part 32 is brought into the OFF state (that is, a state where it does not operate), and the potential of the node n3 is brought into the H level. In this manner, a bias signal in the H level is supplied to the gate of the transistor NM8, and the transistor NM8 as a constant current source is brought into the ON state. In addition, since the transistors NM2 and NM3 are brought into the ON state, and the transistors PM2 and PM3 are brought into the OFF state, the sensor capacitor 50 and the capacitive circuit CAP10 are discharged via the relay terminals CIN0 and CIN1. FIG. 15 illustrates the period in such a state as a third discharging period DP3.

[Third Discharging Detection Period DDP3]

Thereafter, once the potential of the node n4 rises to the threshold level Vth of the inverter part 37, the potential of the node n6 is brought into the L level, and the potential of the node n8 is brought into the H level. Thereafter, once the clock signal CLKIN is brought into the L level, the potential of the node n9 is brought into the H level, and the potential of the node n10 is brought into the L level. FIG. 15 illustrates the period in such a state as a third discharging detection period DDP3.

In this manner, the determination circuit JC outputs the detection signal COUT in the L level and the flag signal COUT2 in the L level in a case where the dielectric element between the electrodes of the sensor capacitor 50 externally connected has not yet been melted in the capacitive sensor circuit 15. In a case where the dielectric element has been melted to some extent, and the sensor capacitor 50 and the capacitive circuit CAP10 get to have substantially equal electrostatic capacity, the determination circuit JC outputs the detection signal COUT in the L level and the flag signal COUT2 in the H level. Then, in a case where the entire dielectric element has been melted, the determination circuit JC outputs the detection signal COUT in the H level and the flag signal COUT2 in the L level.

Therefore, according to the capacitive sensor circuit 15, it is possible to obtain information regarding whether or not the dielectric element of the externally connected sensor capacitor 50 has been melted, that is, information (COUT) indicating whether or not the electrostatic capacity of the sensor capacitor 50 has changed. Moreover, according to the capacitive sensor circuit 15, it is possible to obtain information (COUT2) indicating whether or not the sensor capacitor 50 and the capacitive circuit CAP10 are substantially the same electrostatic capacity.

Additionally, the current is consumed only in the first charging period CP1, the first charging detection period CDP1, the second charging period CP2, the second charging detection period CDP2, the third charging period CP3, and the third charging detection period CDP3 illustrated in FIG. 15, and there is no current consumption in the other periods in the capacitive sensor circuit 15. Therefore, it is possible to reduce current consumption in the entire circuit by setting a low frequency for the clock signal CLKIN even in a case where the electrostatic capacity of the sensor capacitor 50 and the electrostatic capacity of the capacitive circuit CAP10 become substantially equal to each other.

In other words, according to the capacitive sensor circuit 15 including the determination circuit JC illustrated in FIG. 7, it is possible to transmit information regarding the electrostatic capacity of the sensor capacitor 50 to the reader writer 200 without increasing a current even in a case where the sensor capacitor 50 and the capacitive circuit CAP10 get to have substantially equal electrostatic capacity. Additionally, it is possible to transmit information indicating whether or not the sensor capacitor 50 and the capacitive circuit CAP10 have substantially equal electrostatic capacity to the reader writer 200.

Moreover, it is possible to carry out the calibration operation illustrated in FIG. 14 and the detection processing illustrated in FIG. 15 similarly to the aforementioned case where the capacitive circuit CAP10 is used even in a case where the sensor capacitor 50 having relatively high electrostatic capacity is externally connected to the electrode pads P2 and P3, by using the capacitive circuit CAP20.

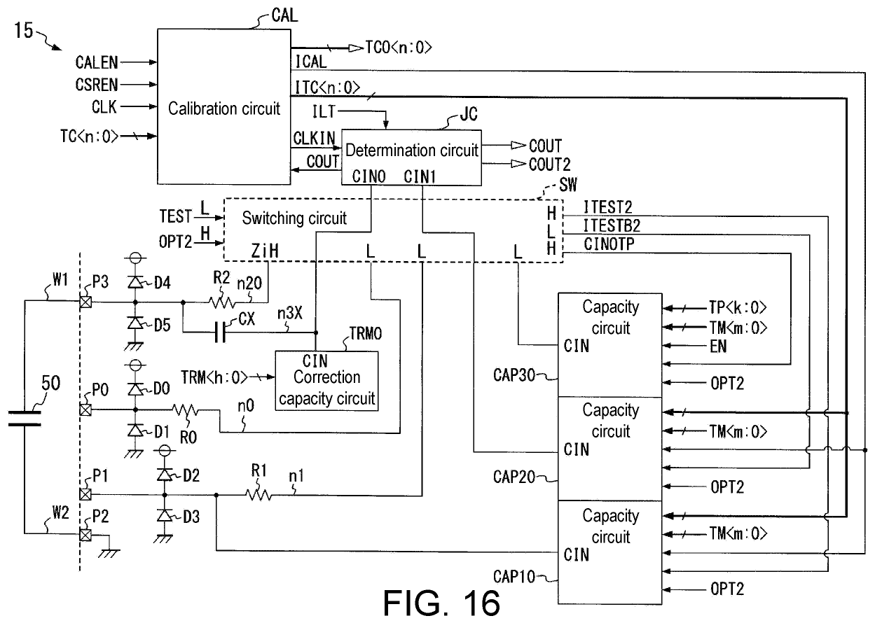

FIG. 16 is a block diagram describing a state inside the capacitive sensor circuit 15 in a state where the sensor capacitor 50 with relatively high electrostatic capacity is connected to the electrode pads P2 and P3.

At this time, the controller 14 supplies the test mode signal TEST in the L level to the switching circuit SW and supplies the leakage test signal ILT in the L level to the determination circuit JC. Further, the controller 14 supplies the switching signal OPT2 in the H level for designating CAP20 out of the capacitive circuits CAP10 and CAP20 to each of the switching circuit SW and the capacitive circuits CAP10, CAP20, and CAP30.

In this manner, the switching circuit SW connects the electrode W1 of the sensor capacitor 50 to the relay terminal CIN0 of the determination circuit JC via the additional capacitor CX and the electrode pad P3 as illustrated in FIG. 16. Additionally, the switching circuit SW connects the capacity connection terminal CIN of the capacitive circuit CAP20 to the relay terminal CIN1 of the determination circuit JC.

Further, the switching circuit SW sets the node n20 into a high-impedance (which will be described as HiZ) state and provides an application in the L level to the nodes n0 and n1 and the capacity connection terminal CIN of the capacitive circuit CAP30 as illustrated in FIG. 16.

Incidentally, the determination circuit charges the sensor capacitor 50 in each of the first to third charging periods CP1 to CP3 illustrated in FIG. 15 to compare the potential of the electrodes of the sensor capacitor 50 with the potential of the capacity connection terminal CIN of the capacitive circuit CAP20.

At this time, more current is consumed for the charging operation in a case where the electrostatic capacity of the sensor capacitor 50 is higher than in a case where it is lower. Further, there is a concern that in a case where a speed of charging the parasitic capacity outside the sensor capacitor 50 and the IC chip 100 is high, the power voltage generated by the power circuit 12 may drop and this may lead to an operation failure.

Thus, the capacitive sensor circuit 15 is provided with the additional capacitor CX such that it is connected to the sensor capacitor 50 in series between the electrode pad P3, to which the one electrode W1 of the sensor capacitor 50 having relatively high electrostatic capacity is connected, and the input terminal CIN0M2 of the switching circuit SW.

The determination circuit JC supplies a charging current sent from its own relay terminal CIN0 to the additional capacitor CX and supplies a charging current sent from the relay terminal CIN1 to the capacitive circuit CAP20 in each of the first to third charging periods CP1 to CP3 illustrated in FIG. 15. In this manner, the capacitive circuit CAP20 is charged, and the additional capacitor CX and the sensor capacitor 50 connected in series via the electrode pad P3 are changed.

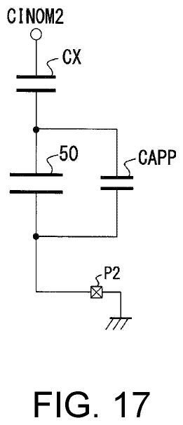

Here, the circuit included between the electrode pad P2 and the input terminal CIN0M2 of the switching circuit SW is represented by an equivalent circuit illustrated in FIG. 17. Also, CAPP illustrated in FIG. 17 represents synthetic parasitic capacity obtained by synthesizing the parasitic capacity of each of the diodes D4 and D5, the resistor R2, and the electrode pad P3 illustrated in FIG. 16.

Therefore, the synthetic electrostatic capacity CAPT viewed from the side of the input terminal CIN0M2 of the switching circuit SW in the equivalent circuit illustrated in FIG. 17 is:

CAPT=(CAP1+CAP2)·CAP2/(CAP1+CAPP+CAP2)
CAP1: the electrostatic capacity of the sensor capacitor 50
CAP2: the electrostatic capacity of the additional capacitor CX
CAPP: the synthetic parasitic capacity of P3, R2, D4, and D5

In this manner, it is possible to reduce the synthetic electrostatic capacity CAPT even if the electrostatic capacity CAP1 of the sensor capacitor 50 is high, by reducing the electrostatic capacity CAP2 of the additional capacitor CX connected thereto in series.

Therefore, it is possible to carry out the aforementioned calibration and the detection processing of the electrostatic capacity without increasing the current consumed for charging of the synthetic electrostatic capacity CAPT even if the electrostatic capacity CAP1 of the sensor capacitor 50 externally connected to the IC chip 100 is relatively high.

Incidentally, there may be a case where an error (which will be referred to as an error of a decrease) in which the result of detection of the electrostatic capacity performed on the sensor capacitor 50 (the potentials of the relay terminals CIN0 and CIN1) becomes lower than a desired value occurs in the capacitive sensor circuit 15 due to variations or the like in manufacturing of the IC chip 100.

Thus, the correction capacitive circuit TRM0 that corrects the error corresponding to the decrease is mounted on the capacitive sensor circuit 15.

To use the correction function of such a correction capacitive circuit TRM0, the error corresponding to the decrease occurring in the result of detecting the electrostatic capacity of the capacitive sensor circuit 15 included in the IC chip after manufacturing is measured first. Then, correction data indicating the amount of error corresponding to the decrease indicated by the measurement result is stored in the memory 16 in advance. In this manner, once power of the IC chip 100 is turned on after shipping of the product, the controller 14 reads the aforementioned correction data from the memory 16. Then, the controller 14 generates a capacity correction trimming signal TRM<h:0> that designates electrostatic capacity corresponding to the amount of error of the decrease indicated by the correction data and supplies this to the correction capacitive circuit TRM0. Therefore, the correction capacitive circuit TRM0 serves as a capacitor having synthetic electrostatic capacity based on the capacitor selected by the capacity correction trimming signal TRM<h:0> from among the capacitors CAP70 to CAP7h and applies the synthetic electrostatic capacity to the node n3X via the capacity connection terminal CIN.

Therefore, the electrostatic capacity of the correction capacitive circuit TRM0 is added to the synthetic electrostatic capacity of the sensor capacitor 50 and the additional capacitor CX. In this manner, even if the detection result of the electrostatic capacity of the sensor capacitor 50 is lower than the desired value due to variations or the like in manufacturing, correction of increasing the electrostatic capacity corresponding to the decrease is carried out. Therefore, it is possible to detect the electrostatic capacity of the sensor capacitor 50 with high accuracy regardless of the variations in manufacturing.

Next, a test operation of internally verifying whether or not the aforementioned detection operation and calibration are performed normally by the capacitive sensor circuit 15 in the IC chip 100 alone will be described.

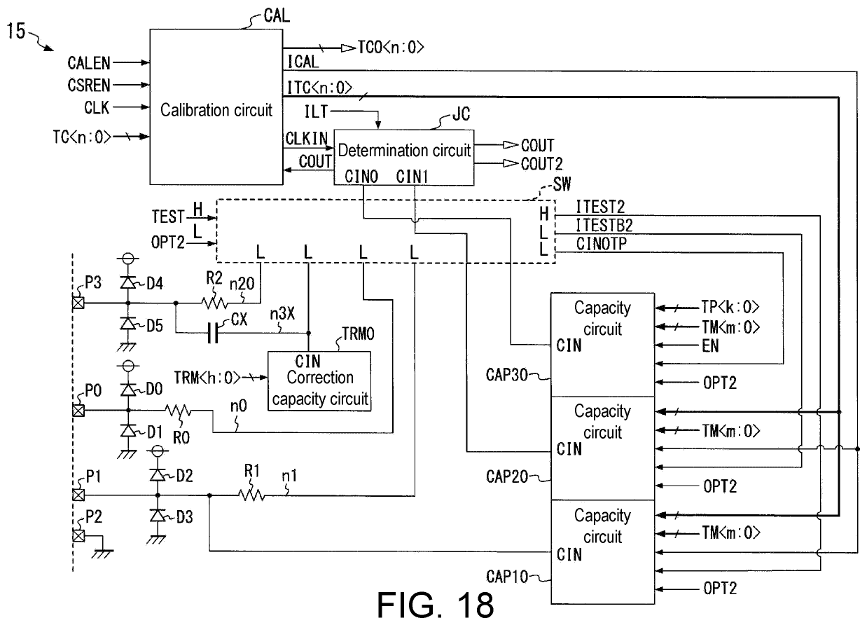

FIG. 18 is a block diagram describing a state inside the capacitive sensor circuit 15 in the test mode for performing the test.

In a case where the test is carried out, the controller 14 supplies the test mode signal TEST in the H level to the switching circuit SW and supplies the leakage test signal ILT in the L level to the determination circuit JC. Also, the controller 14 supplies the enable signal EN in the H level or the L level to the capacitive circuit CAP30. Moreover, the controller 14 supplies the switching signal OPT2 in the L level to each of the switching circuit SW and the capacitive circuits CAP10, CAP20, and CAP30.

In this manner, the switching circuit SW connects the capacity connection terminal CIN of the capacitive circuit CAP30 to the relay terminal CIN0 of the determination circuit JC and connects the capacity connection terminal CIN of the capacitive circuit CAP20 to the relay terminal CIN1 of the determination circuit JC as illustrated in FIG. 18. Further, the switching circuit SW supplies the test signal ITEST2 in the H level to the capacitive circuit CAP10, supplies the inverted test signal ITESTB2 in the L level to the capacitive circuit CAP20, and supplies the signal CIN0TP in the L level to the capacitive circuit CAP30.

Therefore, the selection signals ITX<0> to ITX<n> of the capacitive circuit CAP20 illustrated in FIG. 10 become signals in the same phase as the selection signals ITC<0> to ITC<n> as trimming signals in response to the reception of the inverted test signal ITESTB2 in the L level. Also, the selection signals ITM<0> to ITM<m> illustrated in FIG. 10 become signals of logical AND of the control signal ICAL that is in charge of control of the calibration operation and the margin trimming signal TM<m:0> (that is, the selection signals TM<0> to TM<m>).

Also, the selection signal ITP<k:0> (that is, the selection signals ITP<0> to ITP<k>) of the capacitive circuit CAP30 illustrated in FIG. 11 becomes a signal in the same phase as the capacity value selection signal TP<k:0> (that is, the selection signals TP<0> to TP<k>) in response to reception of the signal CIN0TP in the L level.

Here, it is assumed that the capacitive circuit CAP30 has received the enable signal EN in the H level, the capacity value selection signal TP<k:0> assuming the parasitic capacity outside the IC chip 100, and the margin trimming signal TM<m:0> that sets the electrostatic capacity of the capacitive circuit CAP30 to a half of a difference between the electrostatic capacity before the dielectric element of the sensor capacitor 50 is melted and the electrostatic capacity after the melting. At this time, since the enable signal EN is in the H level and the switching signal OPT2 is in the L level, ITM<m:0> and TM<m:0> in FIG. 11 become signals in the same phase. If it is assumed that the electrostatic capacity of the capacitors CAP50-0 to 50-m illustrated in FIG. 11 is set to be double the electrostatic capacity of the capacitors CAP30-0 to 30-m illustrated in FIG. 10, electrostatic capacity corresponding to the difference between the electrostatic capacity before the dielectric element of the sensor capacitor 50 is melted and the electrostatic capacity after the melting is set for the capacitors CAP50-0 to 50-m.

It is assumed that the calibration circuit CAL has executed the calibration as described above in this state and the trimming signal TC0<n:0> has been set such that the electrostatic capacity of the capacitive circuit CAP20 and the electrostatic capacity of the capacitive circuit CAP30 become equal to each other. The controller 14 supplies data of TCO<n:0> at this time as TC<n:0> to the calibration circuit CAL. Further, the controller 14 supplies the sensor enable signal CSREN in the H level and the calibration enable signal CALEN in the L level to the calibration circuit CAL. At this time, since the calibration enable signal CALEN is in the L level, the control signal ICAL is also brought into the L level, and all of ITM<m:0> in FIG. 10 is also brought into the L level. Since all the capacitors CAP30-0 to 30-m do not function as electrostatic capacity, the electrostatic capacity of the capacitive circuit CAP20 is set to a value obtained by subtracting electrostatic capacity corresponding to a half of the difference between the electrostatic capacity before the dielectric element of the sensor capacitor 50 is melted and the electrostatic capacity after the melting from the electrostatic capacity of the capacitive circuit CAP30.

Further, once the controller 14 supplies the enable signal EN in the L level to the capacitive circuit CAP30, all of ITM<m:0> in FIG. 11 is brought into the L level, and all the capacitors CAP50-0 to 50-m do not function as electrostatic capacity. Therefore, the electrostatic capacity of the capacitive circuit CAP30 is set to a value obtained by subtracting the electrostatic capacity corresponding to a half of the difference between the electrostatic capacity before the dielectric element of the sensor capacitor 50 is melted and the electrostatic capacity after the melting from the electrostatic capacity of the capacitive circuit CAP20.

In other words, it is possible to verify the operations of the capacitive sensor circuit 15 in a state where the electrostatic capacity of the capacitive circuit CAP20 is smaller than the electrostatic capacity of the capacitive circuit CAP30 by the quantity corresponding to the half of the difference between the electrostatic capacity before the dielectric element of the sensor capacitor 50 is melted and the electrostatic capacity after the melting, with the enable signal EN in the H level, the switching signal OPT2 in the L level, and the control signal ICAL in the H level.

Also, it is possible to verify the operations of the capacitive sensor circuit 15 in a state where the electrostatic capacity of the capacitive circuit CAP30 is smaller than the electrostatic capacity of the capacitive circuit CAP20 by the quantity corresponding to the half of the difference between the electrostatic capacity before the dielectric element of the sensor capacitor 50 is melted and the electrostatic capacity after the melting, with the enable signal EN in the L level, the switching signal OPT2 in the L level, and the control signal ICAL in the L level.

In this manner, according to the capacitive sensor circuit 15 in the present embodiment, it is possible to verify whether or not the aforementioned calibration operation and the detection operation will be performed normally in a state where the sensor capacitor 50 as a target of detection has not been externally connected to the IC chip 100, for example, in the stage of a wafer of the IC chip 100.

Next, the leakage test mode of the capacitive sensor circuit 15 will be described.

In the leakage test mode, the controller 14 supplies the leakage test signal ILT in the H level to the determination circuit JC. At this time, the inverted signal IILTB in the determination circuit JC illustrated in FIG. 7 is brought into the L level, and the control signal IILT is brought into the H level.

In this manner, the transistor PM6 illustrated in FIG. 7 receives supply of the control signal IILT in the H level at its gate and is brought into the OFF state. The transistor NM13 receives supply of the control signal IILT in the H level at its gate and is brought into the ON state.

The transistor NM11 receives supply of the inverted signal IILTB in the L level at its gate and is brought into the OFF state. Similarly, the transistor NM12 receives supply of the inverted signal IILTB in the L level at its gate and is brought into the OFF state.

In this manner, both the node n0 and the node n1 illustrated in FIG. 5 are brought into the high-impedance state. Also, the potential of the node n3 illustrated in FIG. 7 is brought into the L level.

The transistor NM8 is brought into the OFF state by the potential of the node n3 being brought into the L level. Therefore, a penetrating current does not flow between the bias signal generation part 32 and the differential amplifier part 35. The period in this state is the leakage test mode.

In this manner, it is possible to bring the node n0 or n20 to which the sensor capacitor 50 is connected and the node n1 to which the capacitive circuit CAP10 is connected into the high-impedance state by the controller 14 supplying the leakage test signal ILT in the H level to the determination circuit JC in the leakage test mode. Therefore, it is possible to execute a screening test for detecting a short-circuit failure in the electrode pad P0 or P3 in the test process after manufacturing of the IC chip 100.

Also, as the switching circuit SW in the above embodiment, any circuit configuration may be employed as long as it is possible to perform the operations as illustrated in FIG. 6.

Also, the electrode pads (P0, P3) to which the one electrode W1 of the sensor capacitor 50 is connected are individually provided in a case where the sensor capacitor having relatively high electrostatic capacity is used and in a case where the sensor capacitor having low electrostatic capacity is used as the sensor capacitor 50 externally connected to the IC chip 100 in the above embodiment. However, these may be replaced with a common electrode pad.

For example, a switch connected to the common electrode pad is provided in the IC chip 100, and a connection destination of the common electrode pad is switched to one end of the resistor R2 or one end of the resistor R0 on the basis of the switching signal OPT2 by the switch.

Alternatively, the electrode pad P0 may be used as the aforementioned common electrode pad by employing a configuration changed such that one end of the additional capacitor CX is connected to the other end of the resistor R0 connected to the electrode pad P0, that is, the node n0 instead of the electrode pad P3 for the capacitive sensor circuit 15.

FIG. 19 is a block diagram illustrating a modification example of the capacitive sensor circuit 15 reflecting such points. Also, the other configurations and operations except for the above change points in the configuration illustrated in FIG. 19 are the same as those of the capacitive sensor circuit 15 illustrated in FIG. 5

Here, the controller 14 supplies the switching signal OPT2 in the L level to the switching circuit SW in a case where the sensor capacitor 50 having relatively low electrostatic capacity is connected to the electrode pads P0 and P2 and calibration or capacity determination as described above is performed. On the other hand, the controller 14 supplies the switching signal OPT2 in the H level to the switching circuit SW in a case where the sensor capacitor 50 having relatively high electrostatic capacity is connected to the electrode pads P0 and P2.

Even if the detection result of the electrostatic capacity of the sensor capacitor 50 is lower than the desired value due to variations or the like in manufacturing, correction of increasing the electrostatic capacity corresponding to the decrease is carried out, and it is thus possible to detect the electrostatic capacity of the sensor capacitor 50 with high accuracy, similarly to the case where the configuration illustrated in FIG. 5 is employed, by employing the configuration illustrated in FIG. 19 as the capacitive sensor circuit 15.

Further, according to the configuration illustrated in FIG. 19, the sensor capacitor 50 is connected to the additional capacitor CX and the input terminal CIN0P of the switching circuit SW via the resistor R0 at the time of detection of the capacity performed on the sensor capacitor 50 having relatively high electrostatic capacity. Therefore, the resistor R0 functions as a noise filter that removes a noise component entering the IC chip 100 via the sensor capacitor 50. In this manner, a decrease in operation error and an improvement in accuracy of the capacitive sensor circuit 15 are achieved.

Additionally, the electrode pad P3 is not used in a case where the configuration illustrated in FIG. 19 is employed as the capacitive sensor circuit 15. Thus, the diodes D4 and D5, the resistor R2, and the input terminal CIN0M of the switching circuit SW connected to the electrode pad P3 may be omitted along with the electrode pad P3 from the capacitive sensor circuit 15 illustrated in FIG. 19.

Also, although the additional capacitor CX is provided inside the IC chip 100 such that it is connected in series with the sensor capacitor 50 externally connected to the IC chip 100 in the aforementioned embodiment, the additional capacitor CX may be connected in series with the sensor capacitor 50 outside the IC chip 100.

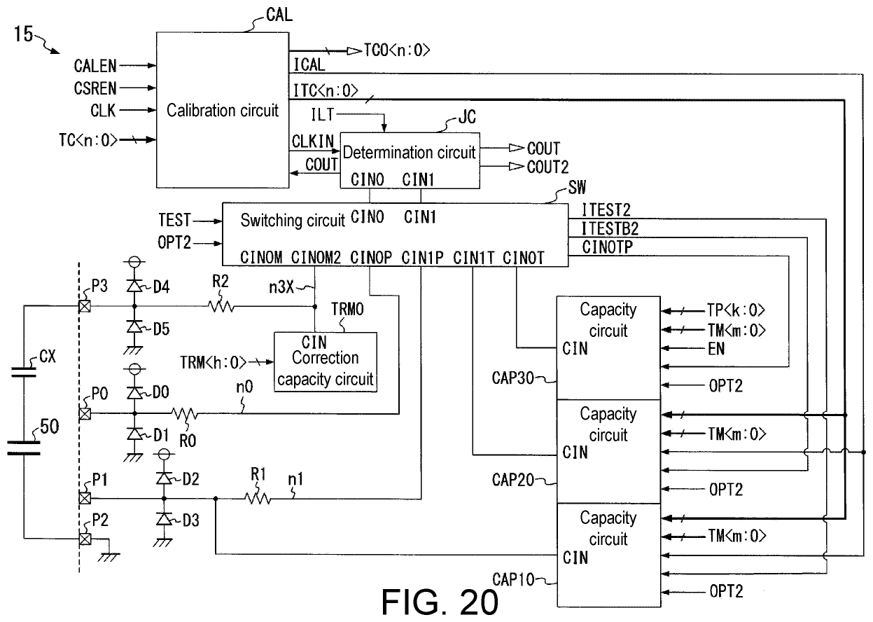

FIG. 20 is a block diagram illustrating another configuration of the capacitive sensor circuit 15 achieved in view of such points. Also, the other configurations except for omission of the additional capacitor CX and the node n20 from the IC chip 100 and connection of the electrode pad P3 to the input terminal CIN0M2 of the switching circuit SW via the resistor R2 and the node n3X in the configuration illustrated in FIG. 20 are the same as those illustrated in FIG. 5 or 19. In other words, a configuration obtained by connecting the additional capacitor CX omitted from the IC chip 100 to the sensor capacitor 50 in series outside the IC chip 100 is externally connected to the electrode pads P3 and P2 in such a configuration.

Also, the configuration in which the electrostatic capacity drops in the case where the ambient environment temperature exceeds the melting point of the wax as the dielectric element is employed as the sensor capacitor 50 in the aforementioned embodiment. However, a configuration in which electrostatic capacity increases in a case where the melting point of the wax is exceeded may be employed.

Additionally, a configuration in which a material irreversibly changes its own form from a solid to a liquid in response to moisture, vibration, or the like may be employed instead of the aforementioned wax as the dielectric element of the sensor capacitor 50.

For example, it is possible to detect a change in moisture as a change in environment as long as the dielectric element irreversibly changes its own form from a solid to a liquid in a case where the dielectric element is exposed to moisture that is equal to or greater than predetermined moisture or is exposed to an environment with lower moisture than predetermined moisture can detect a change in moisture as a change in environment. Alternatively, it is possible to detect reception of vibration as a change in environment as long as the dielectric element irreversibly changes its own form from a solid to a liquid in response to vibration of a magnitude that is equal to or greater than a predetermined magnitude.

Also, although the N-channel MOSFETs (NMOS120-12h) are used as switching elements that set one end of each capacitor to the ground potential in the ON state in the correction capacitive circuit TRM0 illustrated in FIG. 12, P-channel MOSFETs or double diffused MOSFETs (DMOSs) may be used.

In addition, although the correction capacitive circuit TRM0 illustrated in FIG. 12 is provided with a transistor setting one end of each of the capacitors CAP70 to CAP7h to the ground potential for each capacitor, one end of each of at least two capacitors connected in parallel may be able to be set to the ground potential at the same time with a single transistor.

In short, as the IC chip 100 (semiconductor device) including the capacitive sensor circuit 15, any IC chip that is connected between the capacitor (50) that is a target of detection and the first node (n3X) and includes the electrode pad (P0) for externally connecting the capacitor, the following reference capacitive circuit, the determination circuit, and the correction capacitive circuit may be used.

The reference capacitive circuit (CAP10 or CAP20) is a capacitor circuit having the reference electrostatic capacity and applies the reference electrostatic capacity to the second node (n1). The determination circuit (JC) includes the first and second relay terminals (CIN0, CIN1), supplies a charging current from the first relay terminal (CIN0) to the electrode pad (P0) via the first node (n3X), and supplies a charging current from the second relay terminal (CIN1) to the reference capacitive circuit (CAP10) via the second node (n1). Then, the determination circuit (JC) performs detection of the electrostatic capacity of the capacitor (50) and determination regarding whether or not the electrostatic capacity has changed, by comparing the magnitudes of the potentials of the first and second relay terminals. The correction capacitive circuit (TRM0) is a variable capacitor circuit in which its own electrostatic capacity is variable and applies the designated electrostatic capacity to the first node (n3X).

With such a configuration, even if an error of a decrease in which the aforementioned result of detection of the electrostatic capacity performed on the capacitor is lower than the desired electrostatic capacity has occurred due to variations or the like in manufacturing, it is possible to perform correction of increasing the electrostatic capacity corresponding to the error of decrease in electrostatic capacity by using the correction capacitive circuit. It is thus possible to detect the electrostatic capacity of the capacitor with high accuracy.

According to the disclosure, it is possible to perform correction of increasing an error corresponding to a decrease in electrostatic capacity by a correction capacitive circuit in a case where an error of a decrease below desired electrostatic capacity occurs in the result of detecting the electrostatic capacity of the capacitor as a target of detection due to variations in manufacturing.

Therefore, according to the disclosure, it is possible to detect electrostatic capacity of a capacitor with high accuracy regardless of variations in manufacturing.

What is claimed is:

1. A semiconductor device comprising:
an electrode pad connected between a capacitor that is a target of detection and a first node, which is capable of externally connecting the capacitor;
a reference capacitive circuit that has a reference electrostatic capacity and applies the reference electrostatic capacity to a second node;
a determination circuit that includes a first relay terminal and a second relay terminal, supplies a charging current from the first relay terminal to the electrode pad via the first node, supplies a charging current from the second relay terminal to the reference capacitive circuit via the second node, and subsequently detects electrostatic capacity of the capacitor and determines whether or not the electrostatic capacity of the capacitor has changed by comparing magnitudes of potentials at the first relay terminal and the second relay terminal; and
a correction capacitive circuit that applies a designated electrostatic capacity to the first node and is capable of varying the electrostatic capacity.

2. The semiconductor device according to claim 1,
wherein the correction capacitive circuit includes
a capacity connection terminal connected to the first node,
first to h-th (h is an integer that is equal to or greater than two) capacitors, in each of which one of a pair of electrodes thereof is grounded, and
first to h-th transistors that are individually connected to the first to h-th capacitors, and
each of the first to h-th transistors receives a capacity correction signal corresponding to the designated electrostatic capacity, is set in an on state or an off state in accordance with the capacity correction signal, and connects the other one of the pair of electrodes of the capacitor connected to itself to the capacity connection terminal in a case where the transistor is set in the on state.

3. The semiconductor device according to claim 2, comprising:
a non-volatile memory in which correction data indicating electrostatic capacity to be corrected is stored in advance; and
a controller that reads the correction data from the memory in response to turning-on of a power and supplies a signal corresponding to electrostatic capacity indicated by the correction data as the capacity correction signal to the correction capacitive circuit.

4. The semiconductor device according to claim 3,
wherein the reference capacitive circuit includes a first circuit part and a second circuit part that are connected to the second node, each of the first circuit part and the second circuit part being capable of varying the electrostatic capacity,
the semiconductor device includes a calibration circuit that executes calibration of supplying, to the first circuit part, a trimming signal of setting the electrostatic capacity of the first circuit part to electrostatic capacity that changes in a stepwise manner with elapse of time, and
the controller supplies, to the second circuit part, a margin trimming signal for setting electrostatic capacity of the second circuit part as margin electrostatic capacity, stores the trimming signal in the non-volatile memory in response to the determination circuit determining that the potential of the first relay terminal is equal to the potential of the second relay terminal during execution of the calibration, and sets the electrostatic capacity of the first circuit part by using the trimming signal stored in the memory in response to the power being turned on next time.

5. The semiconductor device according to claim 1, comprising:
an additional capacitor connected in series between the first node and the electrode pad.

6. The semiconductor device according to claim 2, comprising:
an additional capacitor connected in series between the first node and the electrode pad.

7. The semiconductor device according to claim 3, comprising:
an additional capacitor connected in series between the first node and the electrode pad.

8. The semiconductor device according to claim 4, comprising:
an additional capacitor connected in series between the first node and the electrode pad.

9. A capacitive sensor device comprising:
a sensor capacitor with electrostatic capacity changing in response to a change in environment;
a first node to which an electrode of the sensor capacitor is connected;
a reference capacitive circuit that has a reference electrostatic capacity and applies the reference electrostatic capacity to a second node;
a determination circuit that includes a first relay terminal and a second relay terminal, supplies a charging current from the first relay terminal to the electrode of the sensor capacitor via the first node, supplies a charging current from the second relay terminal to the reference capacitive circuit via the second node, and subsequently determines whether or not the electrostatic capacity of the sensor capacitor has changed by comparing magnitudes of potentials at the first relay terminal and the second relay terminal; and
a correction capacitive circuit that applies a designated electrostatic capacity to the first node and is capable of varying the electrostatic capacity.

10. The capacitive sensor device according to claim 9,
wherein the correction capacitive circuit includes
a capacity connection terminal connected to the first node,
first to h-th (h is an integer that is equal to or greater than two) capacitors, in each of which one of a pair of electrodes thereof is grounded, and
first to h-th transistors that are individually connected to the first to h-th capacitors, and
each of the first to h-th transistors receives a capacity correction signal corresponding to the designated electrostatic capacity, is set in an on state or an off state in accordance with the capacity correction signal, and connects the other one of the pair of electrodes of the capacitor connected to itself to the capacity connection terminal in a case where the transistor is set in the on state.

11. The capacitive sensor device according to claim 10, comprising:
a non-volatile memory in which correction data indicating electrostatic capacity to be corrected is stored in advance; and
a controller that reads the correction data from the memory in response to turning-on of a power and supplies a signal corresponding to electrostatic capacity indicated by the correction data as the capacity correction signal to the correction capacitive circuit.

12. The capacitive sensor device according to claim 11,
wherein the reference capacitive circuit includes a first circuit part and a second circuit part that are connected to the second node, each of the first circuit part and the second circuit part being capable of varying the electrostatic capacity,
the capacitive sensor device includes a calibration circuit that executes calibration of supplying, to the first circuit part, a trimming signal of setting the electrostatic capacity of the first circuit part to electrostatic capacity that changes in a stepwise manner with elapse of time, and
the controller supplies, to the second circuit part, a margin trimming signal for setting electrostatic capacity of the second circuit part as margin electrostatic capacity, stores the trimming signal in the non-volatile memory in response to the determination circuit determining that the potential of the first relay terminal is equal to the potential of the second relay terminal during execution of the calibration, and sets the electrostatic capacity of the first circuit part by using the trimming signal stored in the memory in response to the power being turned on next time.

13. The capacitive sensor device according to claim 9, comprising:
an additional capacitor connected in series between the first node and the electrode of the sensor capacitor.

14. The capacitive sensor device according to claim 10, comprising:
an additional capacitor connected in series between the first node and the electrode of the sensor capacitor.

15. The capacitive sensor device according to claim 11, comprising:
an additional capacitor connected in series between the first node and the electrode of the sensor capacitor.

16. The capacitive sensor device according to claim 12, comprising:
an additional capacitor connected in series between the first node and the electrode of the sensor capacitor.

17. The capacitive sensor device according to claim 9,
wherein the change in environment is a change in ambient temperature from a state of being lower than a predetermined temperature to a temperature that is equal to or greater than the predetermined temperature, and
a dielectric element sandwiched between a pair of electrodes of the sensor capacitor is a wax having a melting point of the predetermined temperature.
